(19) United States
(12) Patent Application Publication
(10) Pub. No.: US 2016/0033273 A1
(43) Pub. Date: Feb. 4, 2016

(54) METHOD FOR MANUFACTURING PHYSICAL QUANTITY SENSOR, PHYSICAL QUANTITY SENSOR, ELECTRONIC DEVICE, AND MOVING BODY

(71) Applicant: Seiko Epson Corporation, Tokyo (JP)

(72) Inventor: Shinichi KAMISUKI, Shiojiri (JP)

(21) Appl. No.: 14/812,255

(22) Filed: Jul. 29, 2015

(30) Foreign Application Priority Data
Jul. 31, 2014 (JP) 2014-155930
Jul. 31, 2014 (JP) 2014-155933
Nov. 21, 2014 (JP) 2014-236285

(51) Int. Cl. G01C 19/5705; H05K 5/06; G01P 15/125

(52) U.S. Cl. CPC G01C 19/5705; G01P 15/125; H05K 5/06

(57) ABSTRACT

A method for manufacturing a physical quantity sensor of the invention includes preparing a supportive substrate and a seal substrate, the seal substrate including a first recessed portion and a second recessed portion, disposed therein and including a first through hole communicating with the first recessed portion and a second through hole communicating with the second recessed portion; bonding the seal substrate to the supportive substrate such that the gyrosensor element is accommodated in the first recessed portion and such that the acceleration sensor element is accommodated in the second recessed portion; and sealing the first and the second recessed portions by filling the first and the second through holes with first and second seal materials of which the melting points are lower than the melting points or the softening points of the supportive substrate and the seal substrate.

### BACKGROUND

1. Technical Field

The present invention relates to a method for manufacturing a physical quantity sensor, a physical quantity sensor, an electronic device, and a moving body.

2. Related Art

Known is, for example, a composite sensor that is provided with an angular velocity sensor and an acceleration sensor (for example, refer to JP-A-2010-107325).

The composite sensor disclosed in JP-A-2010-107325 is provided with two sensors, a sensor substrate in which each sensor is arranged, and a cap substrate that is bonded to the sensor substrate and that includes two recessed portions accommodating each sensor. The recessed portions accommodating each sensor are sealed in an airtight manner and have different pressure.

In JP-A-2010-107325, in order to manufacture such a composite sensor, each sensor element is arranged in a sensor substrate base material that has a groove, and next, a cap substrate base material is bonded to the sensor substrate base material such that each sensor element is accommodated in each recessed portion. By performing the bonding in a first pressure state where pressure is lower than atmospheric pressure, each sensor element can be sealed while the inside of each recessed portion is in the first pressure state. One of the two recessed portions communicates with the outside through the groove.

The atmosphere of the bonded body that is formed by bonding each base material together is set to a second pressure state where pressure is higher than the first pressure state. Accordingly, the inside of the one recessed portion that communicates with the outside through the groove is in the second pressure state. Last, each base material is deformed as if the groove is crushed by applying heat and pressure in the second pressure state. Accordingly, a second recessed portion is sealed in an airtight manner in the second pressure state. By doing as such, each sensor element can be sealed in an airtight manner at different pressure.

However, when the second recessed portion is sealed, the second recessed portion is sealed such that the groove is crushed. Thus, the dimensional accuracy and reliability of the composite sensor decrease depending on the extent of the sealing.

### SUMMARY

An advantage of some aspects of the invention is to provide a method for manufacturing a physical quantity sensor that has excellent dimensional accuracy and high reliability, the physical quantity sensor, an electronic device, and a moving body.

Such an advantage is accomplished by the following application examples.

### Application Example 1

According to this application example, there is provided a method for manufacturing a physical quantity sensor, the method including: preparing a supportive substrate and a seal substrate, the supportive substrate including a first sensor element and a second sensor element disposed therein and the seal substrate including a first accommodation portion and a second accommodation portion disposed on the supportive substrate side thereof and including a through hole that communicates with the first accommodation portion; bonding the seal substrate to the supportive substrate such that the first sensor element is accommodated on the first accommodation portion side and such that the second sensor element is accommodated on the second accommodation portion side; and sealing the first accommodation portion by filling the through hole with a seal material that has a lower melting point than the melting points or the softening points of the supportive substrate and the seal substrate.

In this case, the first accommodation portion and the second accommodation portion after being sealed can have different pressure by, for example, performing the sealing, after the second accommodation portion is sealed by bonding the supportive substrate and the seal substrate together, in an atmosphere where pressure is different from the pressure inside the sealed second accommodation portion.

It is possible to omit deforming a substrate such that a groove is crushed such as in “JP-A-2010-107325” because the first accommodation portion is sealed through a method of filling the first through hole with the seal material. Thus, the first accommodation portion can be sealed without deforming the supportive substrate. Therefore, a physical quantity sensor that is obtained through the present manufacturing method has excellent dimensional accuracy and high reliability.

The melting point of the seal material is lower than the melting points or the softening points of the supportive substrate and the seal substrate. Accordingly, it is possible to seal the first accommodation portion by melting the seal material while preventing each substrate from being thermally deformed by, for example, heating the seal material, the supportive substrate, and the seal substrate at a temperature higher than or equal to the melting point of the seal material and lower than the melting points or the softening points of the supportive substrate and the seal substrate.

### Application Example 2

In the method for manufacturing a physical quantity sensor according to the application example, preferably, in the bonding, the second accommodation portion is sealed by bonding the supportive substrate and the seal substrate together.

In this case, sealing of the second accommodation portion can be performed at the same time as the bonding. Thus, it is possible to omit separately performing sealing of the second accommodation portion, and by that extent, the present manufacturing method is simplified.

The second accommodation portion is sealed after the bonding. Thus, the first accommodation portion and the second accommodation portion can have different pressure by changing the pressure of the atmosphere of each substrate. Therefore, the first accommodation portion and the second accommodation portion can be sealed in different pressure states.

### Application Example 3

In the method for manufacturing a physical quantity sensor according to the application example, preferably, given that the through hole is a first through hole, the seal material is a first seal material, and the sealing is first sealing, the seal substrate includes a second through hole that communicates with the second accommodation portion, and second sealing is further included in which the second accommodation portion is sealed by a second seal material with which the second through hole is filled.

In this case, the timing of sealing each accommodation portion can be easily shifted. Thus, it is possible to first seal one accommodation portion, change the pressure of the atmosphere of each substrate thereafter, and seal the other accommodation portion. Therefore, the first accommodation portion and the second accommodation portion can be sealed at different pressure.

### Application Example 4

In the method for manufacturing a physical quantity sensor according to the application example, preferably, the seal material includes a metal material, and in the sealing, the first accommodation portion is sealed by melting the seal material.

In this case, the melted seal material can tightly adhere to the inside face of the through hole. Thus, the first accommodation portion can be sealed easily and effectively.

### Application Example 5

In the method for manufacturing a physical quantity sensor according to the application example, preferably, sealing of the first accommodation portion and sealing of the second accommodation portion are performed in atmospheres that have different pressure.

In this case, the first accommodation portion and the second accommodation portion can have different pressure after the sealing.

### Application Example 6

In the method for manufacturing a physical quantity sensor according to the application example, preferably, the first sensor element is a gyrosensor element, and the second sensor element is an acceleration sensor element, and sealing of the first accommodation portion is performed in a first atmosphere where pressure is lower than atmospheric pressure, and sealing of the second accommodation portion is performed in a second atmosphere where pressure is higher than the pressure in the first atmosphere.

In this case, each sensor can exhibit excellent detection accuracy.

### Application Example 7

The method for manufacturing a physical quantity sensor according to the application example, preferably, further including: first sealing the first accommodation portion by filling the first through hole with the first seal material; and second sealing the second accommodation portion by filling the second through hole with the second seal material that has a higher melting point than the first seal material.

In this case, in the manufacturing of a physical quantity sensor, the first seal material and the second seal material can be melted at different timings through, for example, a simple method of changing the temperature at which the supportive substrate and the seal substrate are heated in the same chamber in the state where the first seal material is arranged in the first through hole and where the second seal material is arranged in the second through hole. Thus, it is possible to easily set different timings for sealing of the first accommodation portion and for sealing of the second accommodation portion. Therefore, the sealed first accommodation portion and the sealed second accommodation portion can have different pressure by setting the pressure inside the chamber differently for when the first seal material is melted and for when the second seal material is melted.

As such, a physical quantity sensor of the invention can be obtained through a simple method such as described above and has high producibility.

In the above method, it is possible to omit deforming a substrate such that a groove is crushed as in “JP-A-2010-107325”. Thus, the first accommodation portion and the second accommodation portion can be sealed without deforming the supportive substrate. Therefore, a physical quantity sensor that is obtained by the invention has excellent dimensional accuracy and high reliability.

### Application Example 8

In the method for manufacturing a physical quantity sensor according to the application example, preferably, the first sealing and the second sealing are performed in a same chamber, in the first sealing, the first seal material is melted by setting the temperature inside the chamber to a first temperature that is higher than at least the melting point of the first seal material, and in the second sealing, the second seal material is melted by setting the temperature inside the chamber from the first temperature to a second temperature that is higher than at least the melting point of the second seal material.

In this case, the bonding, the first sealing, and the second sealing can be performed without taking a physical quantity sensor out of the chamber and putting a physical quantity sensor into the chamber. Thus, it is possible to further increase the producibility of a physical quantity sensor.

### Application Example 9

The method for manufacturing a physical quantity sensor according to the application example, preferably, further including: arranging the first seal material in the first through hole and arranging the second seal material in the second through hole before performing the first sealing.

In this case, the bonding, the first sealing, and the second sealing can be performed without taking a physical quantity sensor out of the chamber and putting a physical quantity sensor into the chamber. Thus, it is possible to further increase the producibility of a physical quantity sensor.

### Application Example 10

According to this application example, there is provided a method for manufacturing a physical quantity sensor, the method including: preparing a supportive substrate and a seal substrate, the supportive substrate including a sensor element arranged therein and the seal substrate including a through hole; bonding the supportive substrate and the seal substrate together such that the sensor element is accommodated in at least an accommodation space that is formed by the supportive substrate and the seal substrate; and sealing the accommodation space by arranging a seal material in the through hole, in which a temperature Ta of the supportive substrate and the seal substrate in the bonding is lower than a melting point Tb of the seal material, and in the sealing, the through hole is sealed by melting the seal material at a temperature Tc that is higher than or equal to the melting point Tb.

In this case, it is possible to omit deforming a substrate such that a groove is crushed such as in “JP-A-2010-107325” because the accommodation space is sealed through a method of filling the through hole with the seal material. Thus, the accommodation space can be sealed without deforming the supportive substrate. Therefore, a physical quantity sensor that is obtained through the present manufacturing method has excellent dimensional accuracy and high reliability.

The temperature Ta of the supportive substrate and the seal substrate in the bonding is lower than the melting point Tb of the seal material. Thus, the bonding and the sealing can be performed in the same chamber by, for example, arranging the seal material in advance in the through hole before the bonding and maintaining the arranged state. Thus, the number of times of taking the supportive substrate and the seal substrate out of the chamber and putting the supportive substrate and the seal substrate into the chamber can be decreased. Therefore, by that extent, the present manufacturing method is simplified and has excellent producibility.

When a physical quantity sensor is taken out of and put into the chamber, the temperature of the sensor element temporarily decreases to room temperature from the bonding temperature that is higher than room temperature and afterward, increases again for sealing. Thus, a thermal history (heat cycle) is unnecessarily increased, and this is one of the causes that decrease the reliability of the sensor element. In the invention, the number of times of taking a physical quantity sensor out of the chamber and putting a physical quantity sensor into the chamber can be decreased, and the thermal history can be reduced. Therefore, it is possible to provide a physical quantity sensor having excellent reliability.

### Application Example 11

In the method for manufacturing a physical quantity sensor according to the application example, preferably, the bonding and the sealing are performed in a same chamber.

In this case, it is possible to omit taking the supportive substrate and the seal substrate out of the chamber and putting the supportive substrate and the seal substrate into the chamber after the bonding. Thus, the invention has excellent producibility.

### Application Example 12

In the method for manufacturing a physical quantity sensor according to the application example, preferably, after the bonding, the temperature inside the chamber is maintained higher than or equal to the temperature Ta until the through hole is filled with the seal material.

In this case, the temperature inside the chamber may be increased after the bonding by the difference between the temperature Ta and the temperature Tc. Thus, the through hole can be filled with the seal material by setting the temperature of the seal material to the temperature Tc for a comparatively short time.

### Application Example 13

In the method for manufacturing a physical quantity sensor according to the application example, preferably, arranging the seal material in the through hole before the bonding.

In this case, for example, it is possible to omit arranging the seal material in the through hole after the bonding in the same chamber. Thus, the bonding and the sealing can be performed by putting the seal substrate of which the seal material is arranged in the through hole and the supportive substrate into the chamber.

### Application Example 14

According to this application example, there is provided a method for manufacturing a physical quantity sensor, the method including: a supportive substrate; a first sensor element that is disposed on one face of the supportive substrate; a second sensor element that is disposed on the one face of the supportive substrate at a position different from the first sensor element; a seal substrate that includes a first accommodation portion which accommodates the first sensor element, a second accommodation portion which accommodates the second sensor element, a first through hole which communicates with the first accommodation portion, and a second through hole which accommodates with the second accommodation portion and that is bonded to the one face of the supportive substrate; a first seal material that fills the first through hole and seals the first accommodation portion; and a second seal material that fills the second through hole and seals the second accommodation portion, in which the melting point of the first seal material and the melting point of the second seal material are different from each other.

In this case, in the manufacturing of the physical quantity sensor, the first seal material and the second seal material can be melted at different timings through, for example, a simple method of changing the temperature at which the supportive substrate and the seal substrate are heated in the same chamber in the state where the first seal material is arranged in the first through hole and where the second seal material is arranged in the second through hole. Thus, it is possible to easily set different timings for sealing of the first accommodation portion and for sealing of the second accommodation portion. Therefore, the sealed first accommodation portion and the sealed second accommodation portion can have different pressure by setting the pressure inside the chamber differently for when the first seal material is melted and for when the second seal material is melted.

As such, the physical quantity sensor of the invention can be obtained through a simple method such as described above and has high producibility.

In the above method, it is possible to omit deforming a substrate such that a groove is crushed as in “JP-A-2010-107325”. Thus, the first accommodation portion and the second accommodation portion can be sealed without deforming the supportive substrate. Therefore, the physical quantity sensor of the invention has excellent dimensional accuracy and high reliability.

### Application Example 15

In the method for manufacturing a physical quantity sensor according to the application example, preferably, each of the melting point of the first seal material and the melting point of the second seal material is lower than the melting points or the softening points of the supportive substrate and the seal substrate.

In this case, in the manufacturing of the physical quantity sensor, it is possible to prevent the supportive substrate and the seal substrate from being thermally deformed when the first seal material and the second seal material are melted. Thus, the physical quantity sensor has more excellent dimensional accuracy.

### Application Example 16

In the method for manufacturing a physical quantity sensor according to the application example, preferably, the difference between the melting point of the first seal material and the melting point of the second seal material is greater than or equal to 30° C. and less than or equal to 150° C.

In this case, it is possible to obtain the physical quantity sensor that has high producibility and reliability.

### Application Example 17

In the method for manufacturing a physical quantity sensor according to the application example, preferably, the first sensor element is a gyrosensor element, the second sensor element is an acceleration sensor element, and the melting point of the first seal material is lower than the melting point of the second seal material.

The first accommodation portion is sealed earlier than the second accommodation portion when the temperature at which the supportive substrate and the seal substrate are heated is increased from a temperature lower than the melting point of the first seal material in the same chamber in the state where the first seal material is arranged in the first through hole and where the second seal material is arranged in the second through hole.

The pressure of the first accommodation portion that is sealed first can be lower than the pressure of the second accommodation portion that is sealed later by changing the pressure inside the chamber after the first accommodation portion is sealed and before the second accommodation portion is sealed when the physical quantity sensor is manufactured.

Generally, a gyrosensor element exhibits excellent detection accuracy in an atmosphere where pressure is lower than atmospheric pressure, and an acceleration sensor element exhibits excellent detecting ability in an atmosphere where pressure is higher than the pressure in the case of the gyrosensor.

From this fact, in this case, the first sensor element and the second sensor element can exhibit excellent detection accuracy.

### Application Example 18

In the method for manufacturing a physical quantity sensor according to the application example, preferably, each of the first seal material and the second seal material includes a metal material or a glass material having a low melting point.

In this case, each selection of the material constituting the first seal material and the material constituting the second seal material is facilitated in satisfaction of the condition that the melting points of the materials are lower than those of the supportive substrate and the seal substrate.

### Application Example 19

In the method for manufacturing a physical quantity sensor according to the application example, preferably, the first through hole includes a part of which the area of the transverse section decreases toward the first accommodation portion.

In this case, the seal material before being melted can be stably arranged when the first through hole is filled by melting the seal material.

### Application Example 20

According to this application example, there is provided a method for manufacturing a physical quantity sensor, the method including: a first sensor element; a supportive substrate in which the first sensor element is arranged; a seal substrate that is bonded to the supportive substrate, forms a first accommodation space with the supportive substrate, and includes a through hole which reaches the first accommodation space; and a seal material that seals the through hole, in which the first sensor element is accommodated in the first accommodation space, and the melting point of the seal material is higher than a temperature that is required to bond the supportive substrate and the seal substrate together.

In this case, in the manufacturing of the physical quantity sensor, the first accommodation space can be sealed by heating the seal material to the melting point thereof or higher. Accordingly, it is possible to omit a step of deforming a substrate such that a groove is crushed as in “JP-A-2010-107325”. Thus, the first accommodation space can be sealed without deforming each substrate. Thus, the physical quantity sensor that is obtained through the present manufacturing method has excellent dimensional accuracy and high reliability.

### Application Example 21

In the method for manufacturing a physical quantity sensor according to the application example, preferably, the through hole includes a part of which the area of the transverse section decreases toward the first accommodation space from the opposite side of the seal substrate from the first accommodation space.

In this case, for example, the seal material before being melted can be stably arranged when the through hole is filled by melting the seal material.

### Application Example 22

The method for manufacturing a physical quantity sensor according to the application example, preferably, further including: a second accommodation space and a second sensor element, the second accommodation space being formed by bonding the supportive substrate and the seal substrate together and the second sensor element being accommodated in the second accommodation space, in which a through hole that reaches the second accommodation space is not formed in the second accommodation space.

The air tightness of the second accommodation space can be increased because the second accommodation space is formed by bonding the supportive substrate and the seal substrate together and because a through hole reaching the second accommodation space is not formed in the second accommodation space.

### Application Example 23

According to this application example, there is provided an electronic device including the physical quantity sensor of the application example.

In this case, it is possible to obtain the electronic device having high reliability.

### Application Example 24

According to this application example, there is provided a moving body including the physical quantity sensor of the application example.

In this case, it is possible to obtain the moving body having high reliability.

### BRIEF DESCRIPTION OF THE DRAWINGS

The invention will be described with reference to the accompanying drawings, wherein like numbers reference like elements.

FIG. 1 is a sectional view of a physical quantity sensor according to a first embodiment.

FIG. 2 is a plan view illustrating a gyrosensor element with which the physical quantity sensor illustrated in FIG. 1 is provided.

FIG. 3 is a plan view illustrating an acceleration sensor element with which the physical quantity sensor illustrated in FIG. 1 is provided.

FIGS. 4A to 4C are sectional views for describing a method for manufacturing the physical quantity sensor according to the first embodiment: FIG. 4A is a diagram illustrating a preparing step, FIG. 4B is a diagram illustrating a bonding step, and FIG. 4C is a diagram illustrating an arranging step.

FIGS. 5A to 5C are sectional views for describing the method for manufacturing the physical quantity sensor according to the first embodiment: FIG. 5A is a diagram illustrating a first pressure adjusting step, FIG. 5B is a diagram illustrating a first sealing step, and FIG. 5C is a diagram illustrating a second pressure adjusting step.

FIG. 6 is a sectional view illustrating a second sealing step in the method for manufacturing the physical quantity sensor according to the first embodiment.

FIG. 7 is a sectional view of a physical quantity sensor according to a second embodiment.

FIGS. 8A to 8C are sectional views for describing a method for manufacturing the physical quantity sensor according to the second embodiment: FIG. 8A is a diagram illustrating a preparing step, FIG. 8B is a diagram illustrating an arranging step, and FIG. 8C is a diagram illustrating a bonding step.

FIGS. 9A to 9C are sectional views for describing the method for manufacturing the physical quantity sensor according to the second embodiment: FIG. 9A is a diagram illustrating a first pressure adjusting step, FIG. 9B is a diagram illustrating a first sealing step, and FIG. 9C is a diagram illustrating a second pressure adjusting step.

FIG. 10 is a sectional view illustrating a second sealing step in the method for manufacturing the physical quantity sensor according to the second embodiment.

FIG. 11 is a sectional view illustrating a physical quantity sensor according to a third embodiment.

FIGS. 12A to 12C are sectional views for describing a method for manufacturing the physical quantity sensor according to the third embodiment: FIG. 12A is a diagram illustrating a preparing step, FIG. 12B is a diagram illustrating an arranging step, and FIG. 12C is a diagram illustrating a state where each substrate arranged is inserted into a chamber.

FIGS. 13A and 13B are sectional views for describing the method for manufacturing the physical quantity sensor according to the third embodiment: FIG. 13A is a diagram illustrating a bonding step, and FIG. 13B is a diagram illustrating a pressure adjusting step (in a vacuum state).

FIGS. 14A and 14B are sectional views for describing the method for manufacturing the physical quantity sensor according to the third embodiment: FIG. 14A is a diagram illustrating a pressure adjusting step (in an atmospheric pressure state), and FIG. 14B is a diagram illustrating a sealing step.

FIGS. 15A to 15C are sectional views for describing a method for manufacturing a physical quantity sensor according to a fourth embodiment: FIG. 15A is a diagram illustrating a first pressure adjusting step, FIG. 15B is a diagram illustrating a bonding step, and FIG. 15C is a diagram illustrating a sealing step.

FIG. 16 is a perspective view illustrating a configuration of a mobile (or notebook) personal computer to which an electronic device provided with the physical quantity sensor according to the embodiment is applied.

FIG. 17 is a perspective view illustrating a configuration of a mobile phone (including a PHS) to which the electronic device provided with the physical quantity sensor according to the embodiment is applied.

FIG. 18 is a perspective view illustrating a configuration of a digital still camera to which the electronic device provided with the physical quantity sensor according to the embodiment is applied.

FIG. 19 is a perspective view illustrating a configuration of an automobile to which a moving body provided with the physical quantity sensor according to the embodiment is applied.

FIGS. 20A to 20C are sectional views for describing a method for manufacturing a physical quantity sensor according to a first modification example.

FIGS. 21A to 21C are sectional views for describing the method for manufacturing the physical quantity sensor according to the first modification example.

FIG. 22 is a schematic plan view illustrating a state of a through hole that is disposed in a seal substrate.

FIGS. 23A to 23C are sectional views for describing a method for manufacturing a physical quantity sensor according to a second modification example.

FIGS. 24A to 24C are sectional views for describing the method for manufacturing the physical quantity sensor according to the second modification example.

FIG. 25 is a schematic plan view illustrating a state of a through hole that is disposed in a seal substrate.

### DESCRIPTION OF EXEMPLARY EMBODIMENTS

Hereinafter, detailed descriptions will be provided of a method for manufacturing a physical quantity sensor, the physical quantity sensor, an electronic device, and a moving body of the invention on the basis of exemplary embodiments illustrated in the appended drawings.

### First Embodiment

First, a physical quantity sensor according to a first embodiment will be described.

### 1. Physical Quantity Sensor

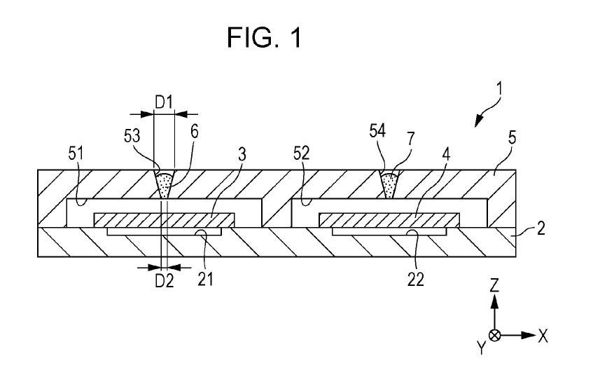

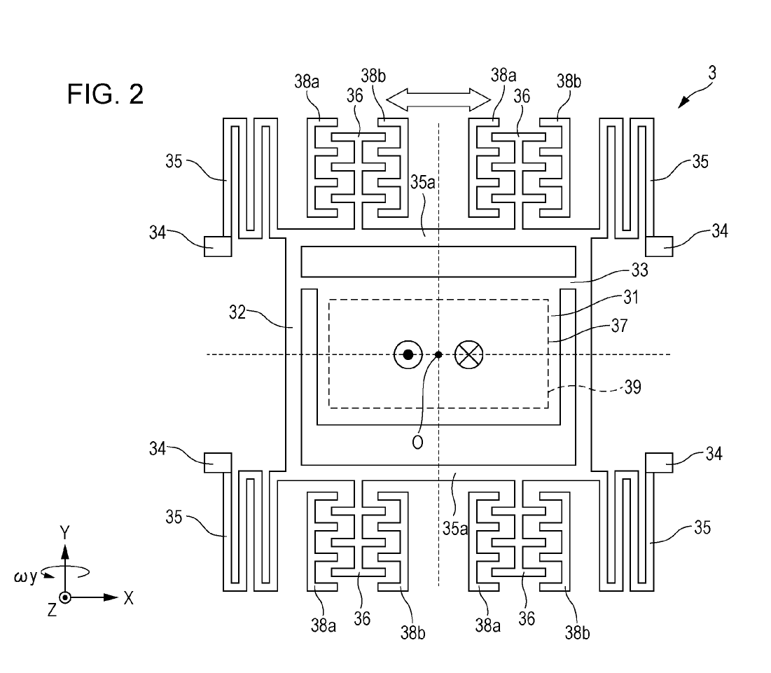

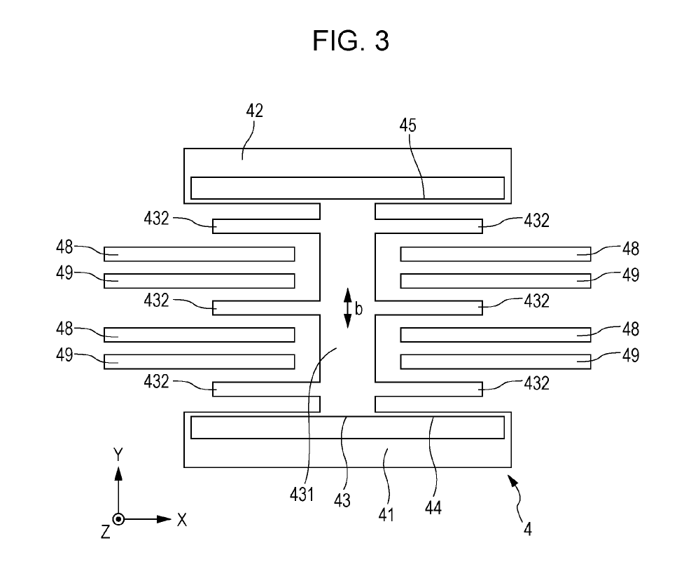

FIG. 1 is a sectional view illustrating the physical quantity sensor according to the present embodiment. FIG. 2 is a plan view illustrating a gyrosensor element with which the physical quantity sensor illustrated in FIG. 1 is provided. FIG. 3 is a plan view illustrating an acceleration sensor element with which the physical quantity sensor illustrated in FIG. 1 is provided.

In the description below, for convenience of description, the front sides of FIG. 2 and FIG. 3 will be referred to as “up”, the rear sides thereof as “down”, the right sides thereof as “right”, and the left sides thereof as “left”. In FIG. 1 to FIG. 7, an X axis, a Y axis, and a Z axis are illustrated as three axes that are orthogonal with respect to each other. In the description below, a direction parallel to the X axis (left-right direction) will be referred to as “X-axis direction”, a direction parallel to the Y axis as “Y-axis direction”, and a direction parallel to the Z axis (up-down direction) as “Z-axis direction”.

A physical quantity sensor 1 illustrated in FIG. 1 includes a supportive substrate 2, a gyrosensor element (first sensor element) 3 and an acceleration sensor element (second sensor element) 4 that are bonded to and supported by the supportive substrate 2, and a seal substrate 5 that is disposed to cover each of the sensor elements 3 and 4.

Hereinafter, each unit constituting the physical quantity sensor 1 will be described.

### Supportive Substrate

The supportive substrate 2 has a function of supporting the gyrosensor element 3 and the acceleration sensor element 4.

The supportive substrate 2 has a shape of a plate, and disposed on the upper face (one of the faces) thereof are hollow portions (recessed portions) 21 and 22. The hollow portion 21, in a plan view of the supportive substrate 2, is formed to include a movable body 31, a vibrating body 32, and four movable drive electrode units 36 of the below-described gyrosensor element 3 and has an inner bottom. Such a hollow portion 21 constitutes an escaping portion that prevents the movable body 31, the vibrating body 32, and the four movable drive electrode units 36 from being in contact with the supportive substrate 2. Accordingly, it is possible to allow the gyrosensor element 3 to be displaced.

The hollow portion 22, meanwhile, in a plan view of the supportive substrate 2, is formed to include a movable portion 43 of the below-described acceleration sensor element 4 and has an inner bottom. Such a hollow portion 22 constitutes an escaping portion that prevents the movable portion 43 of the acceleration sensor element 4 from being in contact with the supportive substrate 2. Accordingly, it is possible to allow the acceleration sensor element 4 to be displaced.

As a material constituting such a supportive substrate 2, specifically, it is preferable to use a highly resistive silicon material or a glass material. Particularly, when the gyrosensor element 3 and the acceleration sensor element 4 are mainly configured of a silicon material, it is preferable to use a glass material (for example, borosilicate glass such as Pyrex (registered trademark) glass) that includes alkali metal ions (movable ions). Accordingly, when each of the sensor elements 3 and 4 is mainly configured of silicon, the supportive substrate 2 and each of the sensor elements 3 and 4 can be anodically bonded together.

A melting point or a softening point (hereinafter, simply referred to as “melting point”) T₂ of the supportive substrate 2, although not particularly limited, for example, is preferably greater than or equal to 500° C. and more preferably greater than or equal to 600° C.

A material constituting the supportive substrate 2 is preferably a material that has a thermal expansion coefficient difference as small as possible with respect to the material constituting the gyrosensor element 3 and the acceleration sensor element 4. Specifically, the thermal expansion coefficient difference between the material constituting the supportive substrate 2 and the material constituting each of the sensor elements 3 and 4 is preferably less than or equal to 3 ppm/° C. Accordingly, when the supportive substrate 2 and each sensor element are placed at a high temperature at the time of bonding and the like thereof, it is possible to reduce residual stress between the supportive substrate 2 and each sensor element.

### Gyrosensor Element

The gyrosensor element 3, as illustrated in FIG. 2, includes the movable body 31, the vibrating body 32, a beam portion 33, four fixed portions 34, four drive spring portions 35, the four movable drive electrode units 36, four pairs of fixed drive electrode units 38a and 38b, a movable detection electrode unit 37, and a fixed detection electrode unit 39.

The fixed portions 34, the drive spring portions 35, the vibrating body 32, the movable drive electrode units 36, the movable body 31, the beam portion 33, and the movable detection electrode unit 37 are integrally formed by, for example, patterning a silicon substrate. The silicon substrate is caused to have conductivity by doping the silicon substrate with an impurity such as phosphorus and boron.

The movable body 31 has a shape of a rectangular plate. Disposed on the outside of the movable body 31 is the vibrating body 32 that has a shape of a quadrangular frame. The movable body 31 and the vibration body 32 are connected by a pair of beam portions 33.

Each beam portion 33 is connected to two of the four corner portions of the movable body 31 on the +Y-axis side. The beam portions 33 are configured to be torsionally deformable, and the torsional deformation of the beam portions 33 allows the movable body 31 to be displaced in the Z-axis direction.

One end portion of each drive spring portion 35 is connected to one of four corner portions of the vibrating body 32. Each drive spring portion 35 is shaped as if being wound several times, and the other end portion of each drive spring portion 35 is connected to one of the four fixed portions 34.

Each fixed portion 34 is fixed to the supportive substrate 2 through, for example, anodic bonding.

Two of the movable drive electrode units 36 are disposed on the +Y-axis side edge of the vibrating body 32 and another two thereof are disposed on the −Y-axis side edge of the vibrating body 32. Each movable drive electrode unit 36 is an electrode that has a shape of teeth of a comb and includes a stem portion protruding from the vibrating body 32 in the Y-axis direction and a plurality of branch portions protruding from the stem portion in the X-axis direction.

The fixed drive electrode units 38a and 38b are disposed to face each other through each movable drive electrode unit 36.

The vibrating body 32 can vibrate in the X-axis direction (along the X axis) owing to the movable drive electrode units 36 and the fixed drive electrode units 38a and 38b.

The movable detection electrode unit 37 is disposed in the movable body 31. The movable detection electrode unit 37 may be formed by doping the movable body 31 with an impurity or may be configured as a metal layer formed on the surface of the movable body 31.

The fixed detection electrode unit 39 is configured as a metal layer that is disposed in the bottom portion of the hollow portion 21 of the supportive substrate 2. The fixed detection electrode unit 39 is disposed to face the movable detection electrode unit 37.

Next, an operation of the gyrosensor element 3 will be described.

Static electricity can be generated between the movable drive electrode unit 36 and the fixed drive electrode units 38a and 38b when a voltage is applied between the movable drive electrode unit 36 and the fixed drive electrode units 38a and 38b. Accordingly, it is possible to vibrate the vibrating body 32 in the X-axis direction while expanding and contracting the drive spring portions 35 in the X-axis direction. The movable body 31 vibrates in the X-axis direction in consequence of the vibration of the vibrating body 32.

When an angular velocity ωy around the Y axis (angular velocity around the Y axis) is applied to the gyrosensor element 3 in the state where the vibrating body 32 vibrates in the X-axis direction, Coriolis force works to displace the movable body 31 in the Z-axis direction. The displacement of the movable body 31 in the Z-axis direction causes the movable detection electrode unit 37 to approach to or recede from the fixed detection electrode unit 39. Thus, the electrostatic capacity between the movable detection electrode unit 37 and the fixed detection electrode unit 39 changes. By detecting the amount of change in the electrostatic capacity between the movable detection electrode unit 37 and the fixed detection electrode unit 39, the angular velocity ωy around the Y axis can be obtained.

### Acceleration Sensor Element

The acceleration sensor element 4 detects the Y-axis directional acceleration. As illustrated in FIG. 3, the acceleration sensor element 4 includes supportive portions 41 and 42, the movable portion 43, connecting portions 44 and 45, a plurality of first fixed electrode fingers 48, and a plurality of second fixed electrode fingers 49. The movable portion 43 includes a base portion 431 and a plurality of movable electrode fingers 432 that protrudes from the base portion 431 toward both sides of the X-axis direction.

Each of the supportive portions 41 and 42 is bonded to the upper face of the supportive substrate 2 and is electrically connected to wiring (not illustrated) through a conductive bump (not illustrated). The movable portion 43 is disposed between the supportive portions 41 and 42. The movable portion 43 is connected to the supportive portion 41 through the connecting portion 44 on the −Y-axis side and is connected to the supportive portion 42 through the connecting portion 45 on the +Y-axis side. Accordingly, the movable portion 43 can be displaced in the Y-axis direction with respect to the supportive portions 41 and 42 as illustrated by an arrow mark b.

The plurality of first fixed electrode fingers 48 is arranged on one of the Y-axis directional sides of the movable electrode fingers 432 and is lined up such that the plurality of first fixed electrode fingers 48 has a shape of teeth of a comb engaging with the correlating movable electrode fingers 432 at an interval. Such a plurality of first fixed electrode fingers 48 is bonded through the base end portion thereof to the upper face of the supportive substrate 2 and is electrically connected to wiring through a conductive bump.

The plurality of second fixed electrode fingers 49, meanwhile, is arranged on the other of the Y-axis directional sides of the movable electrode fingers 432 and is lined up such that the plurality of second fixed electrode fingers 49 has a shape of teeth of a comb engaging with the correlating movable electrode fingers 432 at an interval. Such a plurality of second fixed electrode fingers 49 is bonded through the base end portion thereof to the upper face of the supportive substrate 2 and is electrically connected to wiring through a conductive bump.

Such an acceleration sensor element 4 detects the Y-axis directional acceleration as follows. That is, when the Y-axis directional acceleration is applied to the physical quantity sensor 1, the movable portion 43, on the basis of the magnitude of the acceleration, is displaced in the Y-axis direction while elastically deforming the connecting portions 44 and 45. In consequence of such a displacement, the magnitude of the electrostatic capacity between the movable electrode fingers 432 and the first fixed electrode fingers 48 and the magnitude of the electrostatic capacity between the movable electrode fingers 432 and the second fixed electrode fingers 49 change. Thus, it is possible to detect the acceleration on the basis of a change in these electrostatic capacities (differential signal).

### Seal Substrate

The seal substrate 5 has a function of sealing and protecting the above-described gyrosensor element (first sensor element) 3 and the acceleration sensor element (second sensor element) 4. The seal substrate 5 has a shape of a plate and is bonded to the upper face of the supportive substrate 2. The seal substrate 5 includes a recessed portion (first recessed portion) 51 and a recessed portion (second recessed portion) 52 that are open toward one of the faces (lower face) of the seal substrate 5.

The recessed portion (first recessed portion) 51, as a first accommodation portion, accommodates the gyrosensor element (first sensor element) 3, and the recessed portion (second recessed portion) 52, as a second accommodation portion, accommodates the acceleration sensor element (second sensor element) 4. Each of the recessed portions 51 and 52 has a size capable of sufficiently accommodating each of the sensor elements 3 and 4.

Each of the recessed portions 51 and 52 is formed into a recessed substantially rectangular parallelepiped in the illustrated configuration. However, the recessed portions 51 and 52 are not limited to this and, for example, may have a recessed shape such as a hemisphere and a triangular pyramid.

Through holes 53 and 54 are disposed in the seal substrate 5 to pass through the seal substrate 5 in the thickness direction of the seal substrate 5 as illustrated in FIG. 1. The through hole 53 communicates with the recessed portion 51, and the through hole 54 communicates with the recessed portion 52.

Each of the through holes 53 and 54 has the same configuration. Thus, the through hole 53 will be representatively described hereinafter.

The through hole 53 has a transverse section in the shape of a circle across the Z-axis directional total length of the through hole 53. The diameter of the through hole 53 gradually decreases toward the recessed portion 51. That is, the area of the transverse section of the through hole 53 gradually decreases toward the recessed portion 51. A ratio D1/D2 of a diameter D1 of the upper face opening of the through hole 53 to a diameter D2 of the lower face opening of the through hole 53 is preferably 4 to 100 and more preferably 8 to 35. Accordingly, as will be described below, it is possible to stably arrange a spherical seal material 6a in the through hole 53.

The diameter D1 of the upper face opening of the through hole 53 is not particularly limited and, for example, is preferably greater than or equal to 200 μm and less than or equal to 500 μm and more preferably greater than or equal to 250 μm and less than or equal to 350 μm. The diameter D2 of the lower face opening of the through hole 53 is not particularly limited and, for example, is preferably greater than or equal to 5 μm and less than or equal to 50 μm and more preferably greater than or equal to 10 μm and less than or equal to 30 μm.

A material constituting the seal substrate 5 is not particularly limited provided that the material can exhibit a function such as the one described above. For example, a silicon material or a glass material can be exemplarily used.

A melting point (softening point) T₅ of the seal substrate 5 is not particularly limited and, for example, is preferably greater than or equal to 1000° C. and more preferably greater than or equal to 1100° C.

A method for bonding the seal substrate 5 and the supportive substrate 2 together is not particularly limited. For example, a bonding method using an adhesive or direct bonding such as anodic bonding can be used.

The through hole 53 is filled with a seal material 6, and the through hole 54 is filled with a seal material 7 as illustrated in FIG. 1. Accordingly, each of the recessed portions 51 and 52 is sealed in an airtight manner.

A melting point T₆ of the seal material 6 is lower than the melting point T₂ of the supportive substrate 2 and the melting point T₅ of the seal substrate 5 and, for example, is greater than or equal to 270° C. and less than or equal to 360° C.

A difference Tx of the melting point T₆ of the seal material 6 with respect to the melting point T₂ of the supportive substrate 2 or with respect to the melting point T₅ of the seal substrate 5 is preferably greater than or equal to 20° C. and less than or equal to 700° C. and more preferably greater than or equal to 50° C. and less than or equal to 660° C. Accordingly, the recessed portion 51 can be effectively sealed.

There is a possibility that the seal material 6 is melted when the difference Tx is below the lower limit and when a heating time (bonding time) is comparatively increased in a below-described bonding step. Meanwhile, when the difference Tx is above the upper limit, it is difficult to select materials that constitute the seal material 6, the supportive substrate 2, and the seal substrate 5.

A melting point T₇ of the seal material 7 is lower than the melting point T₂ of the supportive substrate 2 and the melting point T₅ of the seal substrate 5 and, for example, is greater than or equal to 320° C. and less than or equal to 380° C. The difference relationship of the melting point T₇ of the seal material 7 with respect to the melting point T₂ of the supportive substrate 2 or with respect to the melting point T₅ of the seal substrate 5 is said to be the same as above.

The melting point T₆ of the seal material 6 and the melting point T₇ of the seal material 7 satisfy the relationship of T₆<T₇. The melting point T₆ of the seal material 6 and the melting point T₇ of the seal material 7 may be T₆>T₇ or may be T₆=T₇.

Materials constituting the seal materials 6 and 7 are not particularly limited provided that the materials satisfy a melting point relationship such as the one above. For example, a metal material such as an Au—Ge alloy and an Au—Sn alloy and a glass material having a low melting point can be used.

### Method for Manufacturing Physical Quantity Sensor

Next, a method for manufacturing the physical quantity sensor according to the present embodiment will be described.

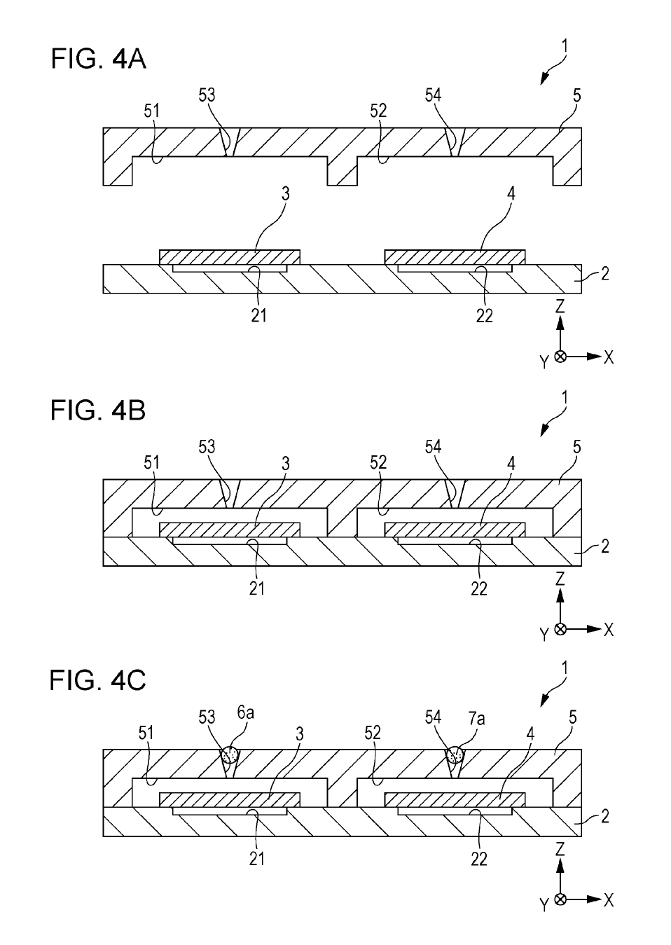

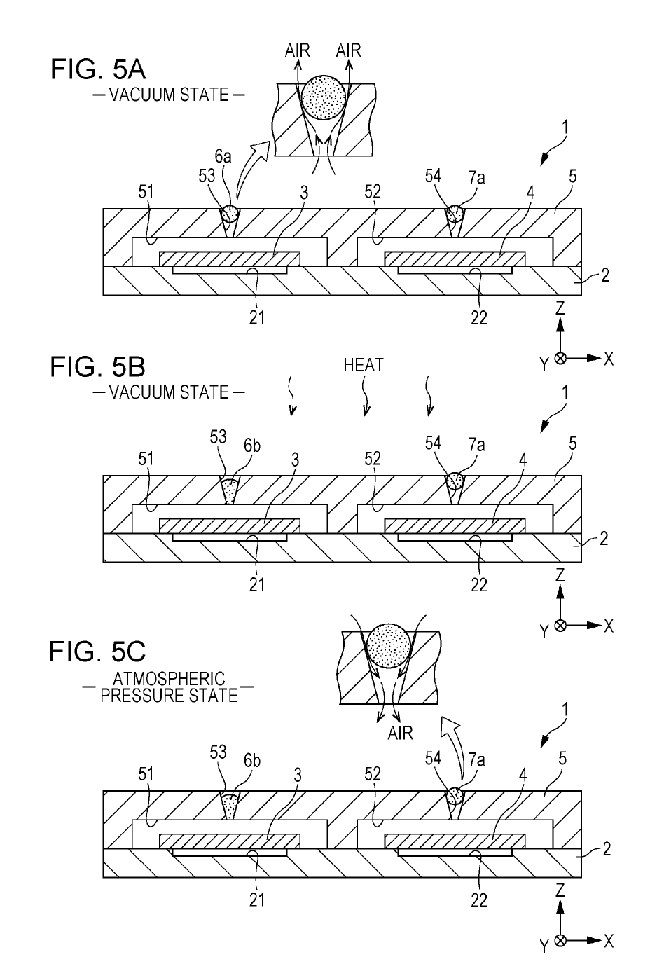

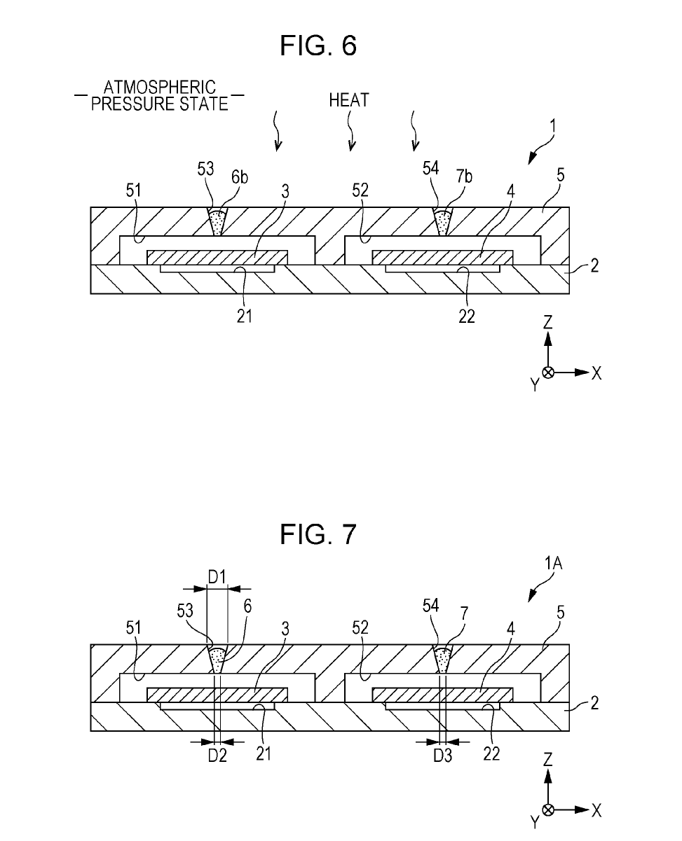

FIGS. 4A to 4C are sectional views for describing the method for manufacturing the physical quantity sensor according to the present embodiment (first embodiment): FIG. 4A is a diagram illustrating a preparing step, FIG. 4B is a diagram illustrating a bonding step, and FIG. 4C is a diagram illustrating an arranging step. FIGS. 5A to 5C are sectional views for describing the method for manufacturing the physical quantity sensor according to the present embodiment (first embodiment): FIG. 5A is a diagram illustrating a first pressure adjusting step, FIG. 5B is a diagram illustrating a first sealing step, and FIG. 5C is a diagram illustrating a second pressure adjusting step. FIG. 6 is a sectional view illustrating a second sealing step in the method for manufacturing the physical quantity sensor according to the present embodiment (first embodiment).

The method for manufacturing the physical quantity sensor according to the present embodiment includes [1] a preparing step, [2] a bonding step, [3] an arranging step, [4] a first pressure adjusting step, [5] a first sealing step, [6] a second pressure adjusting step, and [7] a second sealing step.

An example will be provided in the description below, in which the supportive substrate 2 is configured of a glass material that includes alkali metal ions and in which the seal substrate 5 is configured of a silicon material.

The gyrosensor element 3 and the acceleration sensor element 4 can be formed through a known method, and thus the formation thereof will not be described herein.

### [1] Preparing Step

First, as illustrated in FIG. 4A, the supportive substrate 2 where the gyrosensor element 3 and the acceleration sensor element 4 are disposed on the upper face thereof and the seal substrate 5 are prepared.

The hollow portions 21 and 22 of the supportive substrate 2, the recessed portions 51 and 52 of the seal substrate 5, and the through holes 53 and 54 are formed through etching.

A method for the etching is not particularly limited. For example, a combination of one or two or more of physical etching such as plasma etching, reactive ion etching, beam etching, and light-assisted etching, chemical etching such as wet etching, and the like can be used.

### [2] Bonding Step

Next, as illustrated in FIG. 4B, the seal substrate 5 is arranged on the upper face of the supportive substrate 2 such that the gyrosensor element 3 is accommodated in the recessed portion 51 and such that the acceleration sensor element 4 is accommodated in the recessed portion 52. Then, the upper face of the supportive substrate 2 and the lower face of the seal substrate 5 are bonded together through anodic bonding. Accordingly, it is possible to bond the supportive substrate 2 and the seal substrate 5 together with high strength and air tightness.

In the state where the bonding step is finished, the recessed portion 51 communicates with the outside through the through hole 53, and the recessed portion 52 communicates with the outside through the through hole 54.

### [3] Arranging Step

Next, as illustrated in FIG. 4C, the spherical seal material 6a which is the seal material 6 is arranged in the through hole 53, and a spherical seal material 7a which is the seal material 7 is arranged in the through hole 54. The outside diameters (maximum outside diameters) of the seal materials 6a and 7a are greater than the diameter D2 of the lower face opening of the through hole 53 and are less than the diameter D1 of the upper face opening of the through hole 53. Accordingly, the seal materials 6a and 7a can be arranged in the through holes 53 and 54 (hereinafter, this state will be referred to as “arranged state”).

Each of the through holes 53 and 54, as described above, has a diameter that gradually decreases downward. Accordingly, in the arranged state, the seal material 6a stays at the part where the diameter of the seal material 6a matches the diameter of the through hole 53. Thus, a Z-axis directional movement of the seal material 6a in the through hole 53 is controlled. Furthermore, an XY-plane directional movement of the seal material 6a can also be controlled because the seal material 6a stays at the part where the diameter of the seal material 6a matches the diameter of the through hole 53. Accordingly, it is possible to arrange the seal material 6a still more stably in the through hole 53. This also applies to the seal material 7a in the same manner.

The outside diameters of such seal materials 6a and 7a are preferably greater than or equal to 100 μm and less than or equal to 500 μm and more preferably greater than or equal to 150 μm and less than or equal to 300 μm.

### [4] First Pressure Adjusting Step

Next, as illustrated in FIG. 5A, the atmosphere of the supportive substrate 2 and the seal substrate 5 is set to a vacuum state (first atmosphere). In the present specification, “vacuum state” means the state where pressure is less than or equal to 10 Pa.

In the present embodiment, after the arranging step, the supportive substrate 2 and the seal substrate 5 are arranged in a chamber (not illustrated), and a vacuum is created in the chamber by using a vacuum pump or the like.

The air in the recessed portion 51 is discharged outside the recessed portion 51 through a minute gap between the seal material 6a and the inside face of the through hole 53 by setting the atmosphere of the supportive substrate 2 and the seal substrate 5 to a vacuum state. Accordingly, the inside of the recessed portion 51 is in a vacuum state (also applies to the recessed portion 52 in the same manner).

### [5] First Sealing Step

Next, as illustrated in FIG. 5B, the inside of the chamber is heated, and the seal material 6a in the through hole 53 is melted by setting the temperature inside the chamber to be greater than or equal to the melting point T₆ of the seal material 6a. Accordingly, the seal material 6a that is melted to a liquid form (hereinafter, the liquid seal material 6a will be referred to as “seal material 6b”) adheres tightly to the inside face of the through hole 53 across the whole circumference of the through hole 53. Thus, the space in the recessed portion 51 and the space outside the recessed portion 51 are separated by the seal material 6b. In consequence, the recessed portion 51 is sealed in an airtight manner in the vacuum state. By sealing the recessed portion 51 in the vacuum state, it is possible to prevent damping (vibration damping force) from acting in the gyrosensor element 3 at the time of driving the gyrosensor element 3. In consequence, vibration can be performed with an appropriate amplitude, and the detection sensitivity of the gyrosensor element 3 can be increased.

The seal material 6b has comparatively high surface tension and easily stays in the through hole 53 when a metal material is used as the seal material 6. Therefore, it is possible to prevent the seal material 6b from flowing into the recessed portion 51 from the lower face opening of the through hole 53.

The viscosity of the seal material 6b is preferably high to a certain extent and, specifically, is preferably greater than or equal to 1×10⁻³ Pa·s and more preferably greater than or equal to 3×10⁻³ Pa·s. Accordingly, it is possible to prevent the seal material 6b more effectively from flowing into the recessed portion 51 from the lower face opening of the through hole 53.

The diameter of the lower face opening of the through hole 53 is sufficiently small as described above. Accordingly, it is possible to prevent the seal material 6b still more effectively from flowing into the recessed portion 51 along with the above description.

The temperature inside the chamber in the present step is set to be lower than the melting point T₇ of the seal material 7.

### [6] Second Pressure Adjusting Step

Next, as illustrated in FIG. 5C, the pressure inside the chamber is set to an atmospheric pressure state (second state) where pressure is higher than the pressure in the vacuum state. Examples of a method for setting the atmospheric pressure state from the vacuum state include a method of injecting air, an inert gas such as nitrogen, argon, helium, and neon, or the like into the chamber.

Air (inert gas), at this time, flows into the recessed portion 52 through a minute gap between the spherical seal material 7a and the inside face of the through hole 54 in the same manner as described above. Accordingly, the inside of the recessed portion 52 becomes the atmospheric pressure state from the vacuum state.

In the invention, “second atmosphere” may desirably have higher pressure than the vacuum state and, in addition to the atmospheric pressure state, also includes a decreased pressure state where pressure is lower than atmospheric pressure. The decreased pressure state preferably has a pressure greater than or equal to 0.3×10⁵ Pa and less than or equal to 1×10⁵ Pa and more preferably greater than or equal to 0.5×10⁴ Pa and less than or equal to 0.8×10⁴ Pa. When the recessed portion 52 is sealed in such a decreased pressure state, damping (vibration damping force) having an appropriate magnitude acts in the acceleration sensor element 4 at the time of driving the acceleration sensor element 4, and in consequence, occurrence of unnecessary vibration can be prevented. Thus, it is possible to increase the detection sensitivity of the acceleration sensor element 4.

### [7] Second Sealing Step

As illustrated in FIG. 6, the inside of the chamber is heated, and the seal material 7a in the through hole 54 is melted in the state where the temperature inside the chamber is greater than or equal to the melting point T₇ of the seal material 7a and is less than or equal to the melting point of each substrate. Accordingly, the seal material 7b that is melted to a liquid form tightly adheres to the inside face of the through hole 54 across the whole circumference of the through hole 54. Thus, the space in the recessed portion 52 and the space outside the recessed portion 52 are separated by the seal material 7b. In consequence, the recessed portion 52 is sealed in an airtight manner in the atmospheric pressure state.

Last, the seal materials 6b and 7b are congealed by, for example, returning the temperature thereof to room temperature. Accordingly, the recessed portion 51 is sealed by the seal material 6, and the recessed portion 52 is sealed by the seal material 7.

As such, each of the recessed portion 51 and the recessed portion 52 can be sealed in an airtight manner by passing through the steps [1] to [7] in the state where the recessed portion 51 and the recessed portion 52 have different pressure. Particularly, according to the invention, it is possible to omit a step of deforming a substrate such that a groove is crushed as in “JP-A-2010-107325”. Thus, it is possible to seal the recessed portion and the recessed portion 52 without deforming the supportive substrate 2. Thus, the physical quantity sensor 1 that is obtained through the present manufacturing method has excellent dimensional accuracy and high reliability.

The melting points T₆ and T₇ of the seal materials 6 and 7 are lower than the melting point T₂ of the supportive substrate 2 and the melting point T₅ of the seal substrate 5. Thus, it is possible to prevent the supportive substrate 2 and the seal substrate 5 from being thermally deformed in the first sealing step and in the second sealing step. Thus, the physical quantity sensor 1 has still more excellent dimensional accuracy and still higher reliability.

### Second Embodiment

Next, a physical quantity sensor 1A according to a second embodiment will be described with focus on the differences with respect to the physical quantity sensor 1 according to the first embodiment. The same constituent as in the first embodiment will be designated by the same reference sign, and a duplicate description thereof will not be provided.

First, the physical quantity sensor 1A according to the present embodiment will be described.

### 1. Physical Quantity Sensor

FIG. 7 is a sectional view illustrating the physical quantity sensor according to the present embodiment.

The physical quantity sensor 1A, as illustrated in FIG. 7, includes the supportive substrate 2, the gyrosensor element (first sensor element) 3 and the acceleration sensor element (second sensor element) 4 that are bonded to and supported by the supportive substrate 2, and the seal substrate 5 that is disposed to cover each of the sensor elements 3 and 4.

The supportive substrate 2, the gyrosensor element 3, and the acceleration sensor element 4 are the same as those in the first embodiment (refer to FIG. 2 and FIG. 3), and thus detailed descriptions thereof will not be provided.

### Seal Substrate

The seal substrate 5 has a function of sealing and protecting the above-described gyrosensor element (first sensor element) 3 and the acceleration sensor element (second sensor element) 4. The seal substrate 5 has a shape of a plate and is bonded to the upper face of the supportive substrate 2. The seal substrate 5 includes the recessed portion (first recessed portion) 51 and the recessed portion (second recessed portion) 52 that are open toward one of the faces (lower face) of the seal substrate 5.

The recessed portion (first recessed portion) 51, as a first accommodation portion, accommodates the gyrosensor element (first sensor element) 3, and the recessed portion (second recessed portion) 52, as a second accommodation portion, accommodates the acceleration sensor element (second sensor element) 4. Each of the recessed portions 51 and 52 has a size capable of sufficiently accommodating each of the sensor elements 3 and 4.

Each of the recessed portions 51 and 52 is formed into a recessed substantially rectangular parallelepiped in the illustrated configuration. However, the recessed portions 51 and 52 are not limited to this and, for example, may have a recessed shape such as a hemisphere and a triangular pyramid.

The through holes 53 and 54 are disposed in the seal substrate 5 to pass through the seal substrate 5 in the thickness direction of the seal substrate 5. The through hole 53 communicates with the recessed portion 51, and the through hole 54 communicates with the recessed portion 52. The through holes 53 and 54 have substantially the same configuration except that the diameters of the lower face openings thereof are different. Thus, the through hole 53 will be representatively described hereinafter.

The diameter (width) of the through hole 53 gradually decreases toward the recessed portion 51. That is, the area of the transverse section of the through hole 53 gradually decreases toward the recessed portion 51. The ratio D1/D2 of the diameter D1 of the upper face opening of the through hole 53 to the diameter D2 of the lower face opening of the through hole 53 is preferably 4 to 100 and more preferably 8 to 35. Accordingly, as will be described below, it is possible to stably arrange the spherical seal material 6a in the through hole 53.

The diameter D1 of the upper face opening of the through hole 53 is not particularly limited and, for example, is preferably greater than or equal to 200 μm and less than or equal to 500 μm and more preferably greater than or equal to 250 μm and less than or equal to 350 μm.

In such through holes 53 and 54, the diameter D2 of the through hole 53 is smaller than a diameter D3 of the lower face opening of the through hole 54. Accordingly, as will be described below, it is possible to effectively prevent the liquid seal material 6b having a comparatively low viscosity from flowing into the recessed portion 51.

The diameter D2 of the lower face opening of the through hole 53 is preferably greater than or equal to 10% of the diameter D3 of the lower face opening of the through hole 54 and less than or equal to 90% thereof and more preferably greater than or equal to 30% thereof and less than or equal to 70% thereof. Accordingly, it is possible to prevent the liquid seal material 6b more effectively from flowing into the recessed portion 51.

The air in the recessed portion 51 may not be discharged sufficiently in the first pressure adjusting step described below when the diameter D2 of the lower face opening of the through hole 53 is excessively small. Meanwhile, the effect described above may not be obtained sufficiently when the diameter D2 of the lower face opening of the through hole 53 is excessively large.

The diameter D2 of the lower face opening of the through hole 53 is not particularly limited and, for example, is preferably greater than or equal to 3 μm and less than or equal to 45 μm and more preferably greater than or equal to 5 μm and less than or equal to 25 μm.

The diameter D3 of the lower face opening of the through hole 54 is not particularly limited and, for example, is preferably greater than or equal to 5 μm and less than or equal to 50 μm and more preferably greater than or equal to 10 μm and less than or equal to 30 μm.

A material constituting the seal substrate 5 is not particularly limited provided that the material can exhibit a function such as the one described above. For example, a silicon material or a glass material can be exemplarily used.

The melting point (softening point) T₅ of the seal substrate 5 is not particularly limited and, for example, is preferably greater than or equal to 1000° C. and more preferably greater than or equal to 1200° C. Therefore, using monocrystalline silicon as the seal substrate 5 is exceptionally preferred.

A method for bonding the seal substrate 5 and the supportive substrate 2 together is not particularly limited. For example, a bonding method using an adhesive or direct bonding such as anodic bonding can be used.

The through hole 53 is filled with the seal material 6, and the through hole 54 is filled with the seal material 7 as illustrated in FIG. 7. Accordingly, each of the recessed portions 51 and 52 is sealed in an airtight manner.

The melting point T₆ of the seal material 6 and the melting point T₇ of the seal material 7 are different from each other and, specifically, satisfy the relationship of T₆<T₇. Accordingly, in the first sealing step described below, it is possible to melt only the seal material 6 and seal only the recessed portion 51 by setting the temperature inside the chamber to be greater than or equal to T₆ and less than T₇. Thus, it is possible to make the timing of sealing the recessed portion 51 and the timing of sealing the recessed portion 52 different. Therefore, it is possible to perform sealing so that the recessed portion 51 and the recessed portion 52 have different pressure after being sealed, by setting the pressure inside the recessed portion 51 differently for when the seal material 6 is melted and for when the seal material 7 is melted.

A difference ΔT1 between the melting point T₆ of the seal material 6 and the melting point T₇ of the seal material 7 is preferably greater than or equal to 30° C. and less than or equal to 150° C. and more preferably greater than or equal to 50° C. and less than or equal to 130° C. Accordingly, it is possible to obtain the physical quantity sensor 1A that has high producibility and reliability.

The seal material 7 may be softened or melted at the time of melting of the seal material 6 depending on the temperature inside the chamber in the first sealing step described below when the difference ΔT1 is excessively small. Thus, the recessed portion 52 may be sealed unintentionally. Meanwhile, when the difference ΔT1 is excessively large, a comparatively long time is taken from the melting of the seal material 6 until the melting of the seal material 7, and thus producibility tends to decrease. Furthermore, when the seal material 7 is melted, the temperature of the seal material 6 is excessively higher than the melting point T₆, and the viscosity of the seal material 6 may be excessively decreased. In this case, the seal material 6 easily moves into the recessed portion 51 through the through hole 53.

The melting point T₆ of the seal material 6 and the melting point T₇ of the seal material 7 are lower than the melting point T₂ of the supportive substrate 2 or the melting point T₅ of the seal substrate 5. A difference ΔT2 of the melting point T₆ of the seal material 6 with respect to the melting point T₂ of the supportive substrate 2 or with respect to the melting point T₅ of the seal substrate 5 is, for example, preferably greater than or equal to 20° C. and more preferably greater than or equal to 100° C. Accordingly, the recessed portion 51 can be effectively sealed.

There is a possibility that the seal material 6 is melted when the difference ΔT2 is excessively small and when a heating time (bonding time) is comparatively increased in the below-described bonding step. Meanwhile, when the difference ΔT2 is excessively large, it is difficult to select materials that constitute the seal material 6, the supportive substrate 2, and the seal substrate 5.

The difference relationship of the melting point T₇ of the seal material 7 with respect to the melting point T₂ of the supportive substrate 2 or with respect to the melting point T₅ of the seal substrate 5 is said to be the same as above.

The melting point T₆ of such a seal material 6 is not particularly limited and, for example, is preferably greater than or equal to 270° C. and less than or equal to 400° C. and more preferably greater than or equal to 290° C. and less than or equal to 380° C. The melting point T₇ of the seal material 7 is not particularly limited and, for example, is preferably greater than or equal to 320° C. and less than or equal to 450° C. and more preferably greater than or equal to 340° C. and less than or equal to 430° C.

Materials constituting the seal materials 6 and 7 are not particularly limited provided that the materials satisfy a melting point relationship such as the one above. For example, a metal material such as an Au—Ge alloy and an Au—Sn alloy and a glass material having a low melting point such as lead glass, bismuth glass, or vanadium glass can be used. Accordingly, each selection of the materials constituting the seal materials 6 and 7 is facilitated in satisfaction of the condition that the melting points of the materials are lower than the melting point T₂ of the supportive substrate 2 and the melting point T₅ of the seal substrate 5.

The air tightness of the recessed portions 51 and 52 after being sealed can be secured when the seal materials 6 and 7 are configured of metal materials such as the one above, and thus, the physical quantity sensor 1A has excellent reliability.

Meanwhile, the affinity of the seal materials 6 and 7 with the seal substrate 5 can be improved when the seal materials 6 and 7 are configured of a glass material having a low melting point as described above and when the seal substrate 5 is configured of a glass material. Therefore, the physical quantity sensor 1A has excellent reliability.

### Method for Manufacturing Physical Quantity Sensor

Next, a method for manufacturing the physical quantity sensor according to the present embodiment will be described.

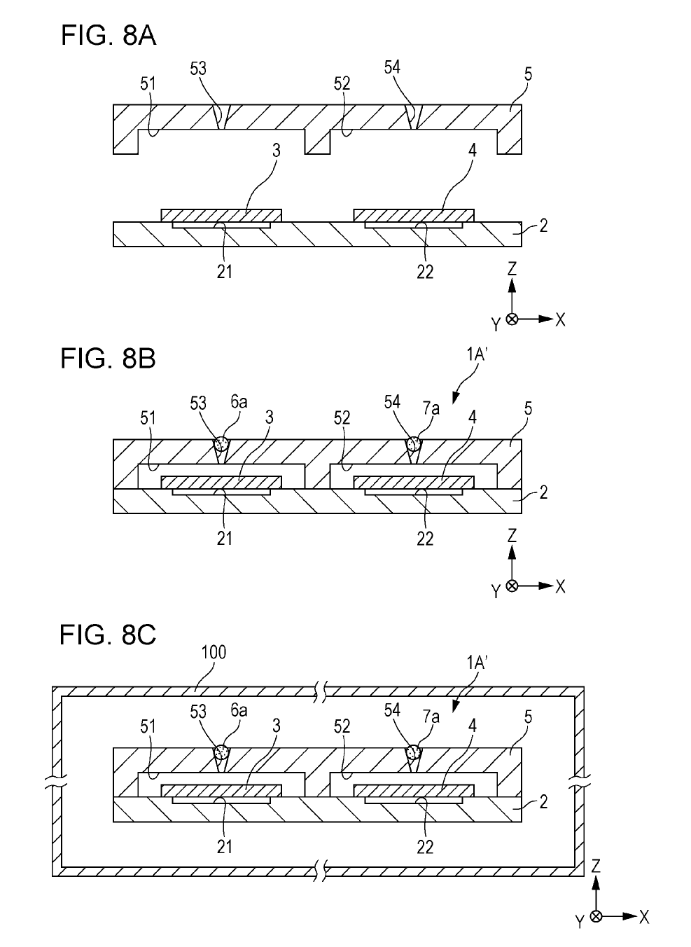

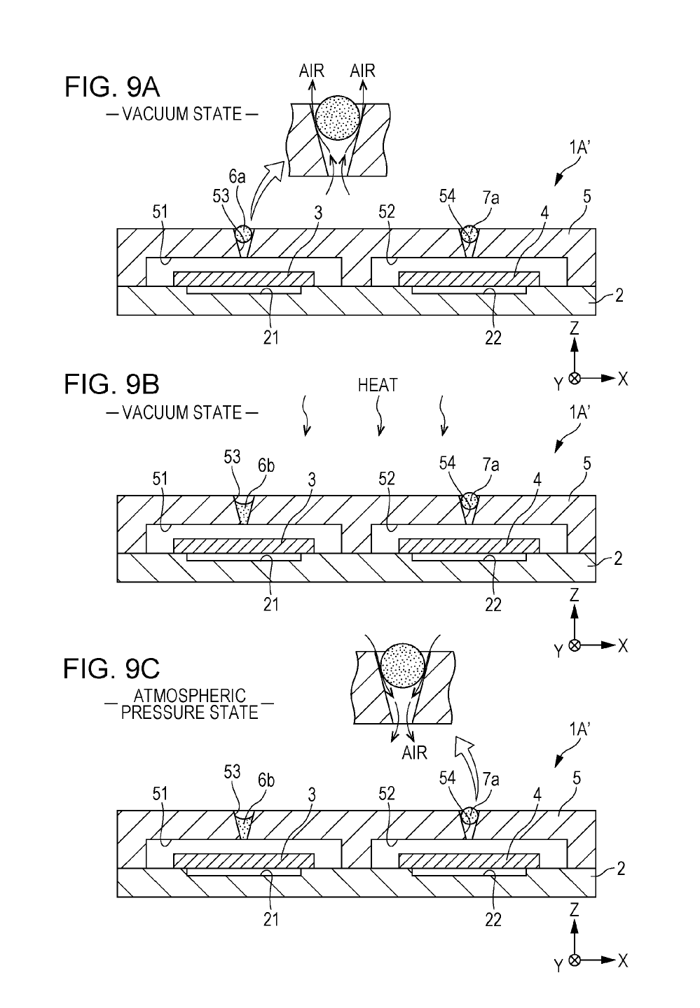

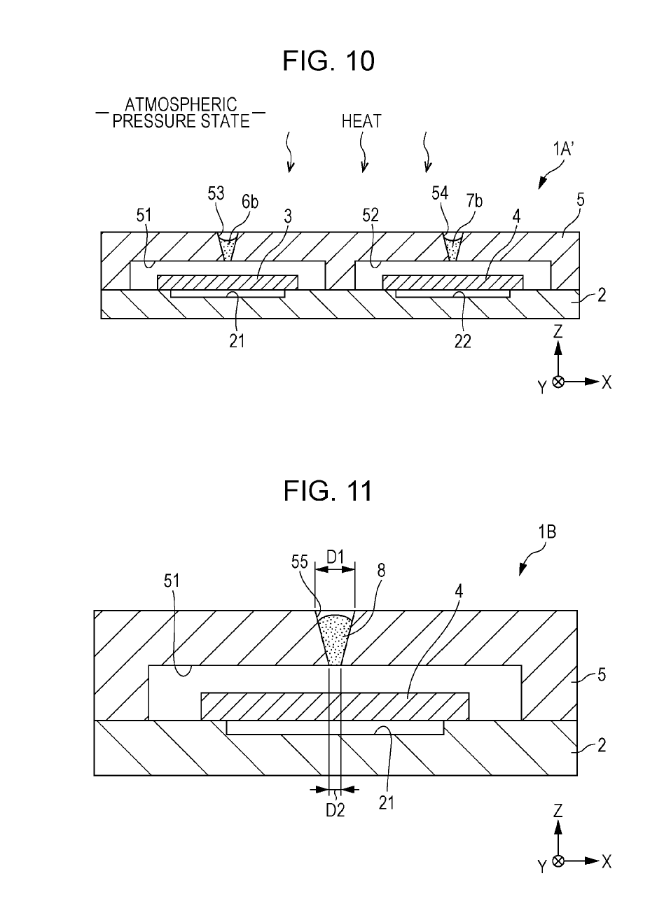

FIGS. 8A to 8C are sectional views for describing the method for manufacturing the physical quantity sensor according to the present embodiment: FIG. 8A is a diagram illustrating a preparing step, FIG. 8B is a diagram illustrating an arranging step, and FIG. 8C is a diagram illustrating a bonding step. FIGS. 9A to 9C are sectional views for describing the method for manufacturing the physical quantity sensor according to the present embodiment (second embodiment): FIG. 9A is a diagram illustrating a first pressure adjusting step, FIG. 9B is a diagram illustrating a first sealing step, and FIG. 9C is a diagram illustrating a second pressure adjusting step. FIG. 10 is a sectional view illustrating a second sealing step in the method for manufacturing the physical quantity sensor according to the present embodiment.

The method for manufacturing the physical quantity sensor according to the present embodiment includes [1] a preparing step, [2] an arranging step, [3] a bonding step, [4] a first pressure adjusting step, [5] a first sealing step, [6] a second pressure adjusting step, and [7] a second sealing step.

A chamber 100 is only illustrated in FIG. 8C, and the illustration of the chamber 100 is not provided in FIGS. 9A to 9C and in FIG. 10. However, in the present embodiment, steps from [3] the bonding step are performed in the chamber 100 until [7] the second sealing step is completed.

An example will be provided in the description below, in which the supportive substrate 2 is configured of a glass material that includes alkali metal ions and in which the seal substrate 5 is configured of a silicon material.

The gyrosensor element 3 and the acceleration sensor element 4 can be formed through a known method, and thus the formation thereof will not be described herein.

### [1] Preparing Step

First, as illustrated in FIG. 8A, the supportive substrate 2 where the gyrosensor element 3 and the acceleration sensor element 4 are disposed on the upper face thereof and the seal substrate 5 are prepared.

The preparing step is the same as that in the first embodiment and thus will not be described in detail.

### [2] Arranging Step

Next, as illustrated in FIG. 8B, the spherical seal material 6a which is the seal material 6 is arranged in the through hole 53, and the spherical seal material 7a which is the seal material 7 is arranged in the through hole 54.

The arranging step is the same as that in the first embodiment and thus will not be described in detail.

### [3] Bonding Step

Next, as illustrated in FIG. 8C, the seal substrate 5 is arranged on the upper face of the supportive substrate 2 such that the gyrosensor element 3 is accommodated in the recessed portion 51 and such that the acceleration sensor element 4 is accommodated in the recessed portion 52 (hereinafter, this state will be referred to as “physical quantity sensor 1A′”). The physical quantity sensor 1A′ is put into the chamber 100. The seal materials 6a and 7a may be arranged in the through holes 53 and 54 after the seal substrate 5 is arranged on the upper face of the supportive substrate 2.

The upper face of the supportive substrate 2 and the lower face of the seal substrate 5 are bonded together through anodic bonding. Accordingly, it is possible to bond the supportive substrate 2 and the seal substrate 5 together with high strength and air tightness.

The temperature inside the chamber 100 in the anodic bonding, that is, a temperature Ta of the physical quantity sensor 1A′ at the time of the anodic bonding is not particularly limited provided that the temperature Ta is lower than the melting point T₆ of the seal material 6a and is preferably greater than or equal to 150° C. and less than or equal to 380° C. and more preferably greater than or equal to 250° C. and less than or equal to 360° C. Accordingly, it is possible to prevent the seal materials 6a and 7a from being melted to seal the recessed portions 51 and 52 when anodic bonding is performed in the arranged state.

In the bonding step, when the temperature Ta is excessively low, the bonding strength between the supportive substrate 2 and the seal substrate 5 may not be sufficient. When the temperature Ta is excessively high, the seal material 6a may be softened to seal the recessed portion 51.

In the state where the bonding step is finished, the recessed portion 51 communicates with the outside through the through hole 53, and the recessed portion 52 communicates with the outside through the through hole 54.

### [4] First Pressure Adjusting Step

Next, as illustrated in FIG. 9A, the atmosphere of the supportive substrate 2 and the seal substrate 5 is set to the first pressure state (vacuum state). In the present specification, “vacuum state” means the state where pressure is less than or equal to 10 Pa.

In the present embodiment, after the arranging step, the supportive substrate 2 and the seal substrate 5 are arranged in the chamber 100, and a vacuum is created in the chamber 100 by using a vacuum pump or the like.

The air in the recessed portion 51 is discharged outside the recessed portion 51 through a minute gap between the seal material 6a and the inside face of the through hole 53 by setting the atmosphere of the supportive substrate 2 and the seal substrate 5 to the first pressure state. Accordingly, the inside of the recessed portion 51 is in the first pressure state (also applies to the recessed portion 52 in the same manner).

### [5] First Sealing Step

Next, as illustrated in FIG. 9B, the inside of the chamber 100 is heated, and the seal material 6a in the through hole 53 is melted by setting the temperature inside the chamber 100 to a temperature Tb that is greater than or equal to the melting point T₆ of the seal material 6a and less than the melting point T₇ of the seal material 7a. Accordingly, the seal material 6a that is melted to a liquid form (hereinafter, the liquid seal material 6a will be referred to as “seal material 6b”) adheres tightly to the inside face of the through hole 53 across the whole circumference of the through hole 53. Thus, the space in the recessed portion 51 and the space outside the recessed portion 51 are separated by the seal material 6b. In consequence, the recessed portion 51 is sealed in an airtight manner in the first pressure state. By sealing the recessed portion 51 in the first pressure state, it is possible to prevent damping (vibration damping force) from acting in the gyrosensor element 3 at the time of driving the gyrosensor element 3. In consequence, vibration can be performed with an appropriate amplitude, and the detection sensitivity of the gyrosensor element 3 can be increased.

The seal material 6b has comparatively high surface tension and easily stays in the through hole 53 when a metal material and a glass material having a low melting point are used as the seal material 6. Therefore, it is possible to prevent the seal material 6b from flowing into the recessed portion 51 from the lower face opening of the through hole 53.

The viscosity of the seal material 6b is preferably high to a certain extent and, specifically, is preferably greater than or equal to 1×10⁻³ Pa·s and more preferably greater than or equal to 3×10⁻³ Pa·s. Accordingly, it is possible to prevent the seal material 6b more effectively from flowing into the recessed portion 51 from the lower face opening of the through hole 53.

The diameter of the lower face opening of the through hole 53 is sufficiently small as described above. Accordingly, it is possible to prevent the seal material 6b still more effectively from flowing into the recessed portion 51 along with the above description.

A difference ΔT3 between the temperature Tb inside the chamber 100 and the melting point T₆ of the seal material 6a in the present step is preferably greater than or equal to 10° C. and less than or equal to 100° C. and more preferably greater than or equal to 40° C. and less than or equal to 70° C.

The seal material 6a may be softened and deformed in the through hole 53 depending on the material constituting the seal material 6a when the difference ΔT3 is excessively large. Furthermore, a comparatively long time is taken to change the temperature inside the chamber 100 from the temperature Ta to the temperature Tb. Meanwhile, when the difference ΔT3 is excessively small, although also depending on the material constituting the seal material 6a and the size and the like of the seal material 6a, a comparatively long time is taken from when the temperature inside the chamber 100 becomes the temperature Tb until the seal material 6a is melted.

### [6] Second Pressure Adjusting Step

Next, as illustrated in FIG. 9C, the pressure inside the chamber 100 is set to a second pressure state where pressure is higher than the pressure in the first pressure state. Examples of a method for setting the second pressure state from the first pressure state include a method of injecting an inert gas such as nitrogen, argon, helium, and neon, air, or the like into the chamber 100.

An inert gas, air, or the like, at this time, flows into the recessed portion 52 through a minute gap between the spherical seal material 7a and the inside face of the through hole 54 in the same manner as described above. Accordingly, the inside of the recessed portion 52 becomes the second pressure state from the first pressure state.

In the invention, “second atmosphere” may desirably have higher pressure than the first pressure state and also includes the atmospheric pressure state and a decreased pressure state where pressure is lower than atmospheric pressure. The decreased pressure state preferably has a pressure greater than or equal to 0.3×10⁵ Pa and less than or equal to 1×10⁵ Pa and more preferably greater than or equal to 0.5×10⁴ Pa and less than or equal to 0.8×10⁴ Pa. When the recessed portion 52 is sealed in such a decreased pressure state, damping (vibration damping force) having an appropriate magnitude acts in the acceleration sensor element 4 at the time of driving the acceleration sensor element 4, and in consequence, occurrence of unnecessary vibration can be prevented. Thus, it is possible to increase the detection sensitivity of the acceleration sensor element 4.

### [7] Second Sealing Step

As illustrated in FIG. 10, in the second pressure state, the inside of the chamber 100 is heated, and the temperature inside the chamber 100 is set to a temperature Tc that is greater than or equal to the melting point T₇ of the seal material 7a and less than or equal to the melting point T₂ of the supportive substrate 2 and the melting point T₅ of the seal substrate 5. Accordingly, the seal material 7a in the through hole 54 is melted. Thus, the seal material 7b that is melted to a liquid form tightly adheres to the inside face of the through hole 54 across the whole circumference of the through hole 54. Therefore, the space in the recessed portion 52 and the space outside the recessed portion 52 are separated by the seal material 7b. In consequence, the recessed portion 52 is sealed in an airtight manner in the second pressure state.

The seal material 6b in the present step has the same temperature as the seal material 7b, that is, a temperature higher than the temperature of the seal material 6b in the first sealing step when the seal material 7a is heated up to a temperature greater than or equal to the melting point T₇ and becomes the seal material 7b. Thus, in the present step, the viscosity of the seal material 6b tends to decrease lower than the viscosity of the seal material 6b in the first sealing step. However, as described above, the diameter D2 of the through hole 53 is sufficiently small. Accordingly, it is possible to prevent the seal material 6b more effectively from flowing into the recessed portion 51.

A difference ΔT4 between the temperature Tc inside the chamber 100 and the melting point T₇ of the seal material 7a in the present step is preferably greater than or equal to 30° C. and less than or equal to 100° C. and more preferably greater than or equal to 50° C. and less than or equal to 80° C.

A long time is taken to change the temperature inside the chamber 100 from the temperature Tb to the temperature Tc, and the viscosity of the seal material 6b tends to further decrease when the difference ΔT4 is excessively large. Meanwhile, when the difference ΔT4 is excessively small, although also depending on the material constituting the seal material 7a, a long time tends to be taken from when the temperature inside the chamber 100 becomes the temperature Tc until the seal material 7a is melted.

Last, after [7] the second sealing step is completed, the seal materials 6b and 7b are congealed by, for example, returning the temperature thereof to room temperature. Accordingly, it is possible to obtain the physical quantity sensor 1A.

As such, each of the recessed portion 51 and the recessed portion 52 can be sealed in an airtight manner by passing through the steps [1] to [7] in the state where the recessed portion 51 and the recessed portion 52 have different pressure. Particularly, according to the invention, it is possible to omit a step of deforming a substrate such that a groove is crushed as in “JP-A-2010-107325”. Thus, it is possible to seal the recessed portion and the recessed portion 52 without deforming the supportive substrate 2. Thus, the physical quantity sensor 1A that is obtained through the present manufacturing method has excellent dimensional accuracy and high reliability.

Furthermore, it is possible to perform the steps of [3] the bonding step to [7] the second sealing step once the physical quantity sensor 1A′ is put into the chamber 100, without taking the physical quantity sensor 1A′ out of the chamber 100 and putting the physical quantity sensor 1A′ into the chamber 100 anymore. Thus, the present manufacturing method is exceptionally simple and has high producibility. In addition, it is possible to effectively prevent or suppress influence on the physical quantity sensor 1A′ due to repeated heating and cooling of the physical quantity sensor 1A′ (for example, a crack and the like occurring in each substrate). Thus, according to the invention, it is possible to obtain the physical quantity sensor 1A that has exceptionally high reliability.

It is also possible to collectively obtain a plurality of physical quantity sensors 1A by putting a plurality of physical quantity sensors 1A′ in one chamber 100 and performing the steps [1] to [7].

### Third Embodiment

First, a physical quantity sensor 1B according to a third embodiment will be described.

### 1. Physical Quantity Sensor

FIG. 11 is a sectional view illustrating the physical quantity sensor according to the present embodiment.

The physical quantity sensor 1B illustrated in FIG. 11 includes the supportive substrate 2, the acceleration sensor element (sensor element) 4 that are bonded to and supported by the supportive substrate 2, the seal substrate 5 that is disposed to cover the acceleration sensor element (sensor element) 4, and a seal material 8.

Hereinafter, each unit constituting the physical quantity sensor 1B will be described.

### Supportive Substrate

The supportive substrate 2 has a function of supporting the acceleration sensor element 4.

The supportive substrate 2 has a shape of a plate, and disposed on the upper face (one of the faces) thereof is the hollow portion 21.

The hollow portion 21, in a plan view of the supportive substrate 2, is formed to include the movable portion 43 of the below-described acceleration sensor element 4 and has an inner bottom. Such a hollow portion 21 constitutes an escaping portion that prevents the movable portion 43 of the acceleration sensor element 4 from being in contact with the supportive substrate 2. Accordingly, it is possible to allow the acceleration sensor element 4 to be displaced.

As a material constituting such a supportive substrate 2, specifically, it is preferable to use a highly resistive silicon material or a glass material. Particularly, when the acceleration sensor element 4 is mainly configured of a silicon material, it is preferable to use a glass material (for example, borosilicate glass such as Pyrex (registered trademark) glass) that includes alkali metal ions (movable ions). Accordingly, when the acceleration sensor element 4 is mainly configured of silicon, the supportive substrate 2 and the acceleration sensor element 4 can be anodically bonded together.

The melting point or the softening point (hereinafter, simply referred to as “melting point”) T₂ of the supportive substrate 2, although not particularly limited, for example, is preferably greater than or equal to 500° C. and more preferably greater than or equal to 600° C.

A material constituting the supportive substrate 2 is preferably a material that has a thermal expansion coefficient difference as small as possible with respect to the material constituting the acceleration sensor element 4. Specifically, the thermal expansion coefficient difference between the material constituting the supportive substrate 2 and the material constituting the acceleration sensor element 4 is preferably less than or equal to 3 ppm/° C. Accordingly, when the supportive substrate 2 and the acceleration sensor element 4 are placed at a high temperature at the time of bonding and the like thereof, it is possible to reduce residual stress between the supportive substrate 2 and the acceleration sensor element 4.

### Acceleration Sensor Element

The acceleration sensor element 4 detects the Y-axis directional acceleration. The acceleration sensor element 4 is the same as that in the first embodiment (refer to FIG. 3) and thus will not be described in detail.

### Seal Substrate

The seal substrate 5 has a function of sealing and protecting the acceleration sensor element (sensor element) 4. The seal substrate 5 has a shape of a plate and is bonded to the upper face of the supportive substrate 2. The seal substrate 5 includes the recessed portion (accommodation space) 51 that is open toward one of the faces (lower face) of the seal substrate 5.

The recessed portion (accommodation space) 51 accommodates the acceleration sensor element (sensor element) 4 and has a size capable of sufficiently accommodating the acceleration sensor element (sensor element) 4.

The recessed portion (accommodation space) 51 is formed into a recessed substantially rectangular parallelepiped in the illustrated configuration. However, the recessed portion 51 may have a recessed shape such as a hemisphere and a triangular pyramid.

A through hole 55 is disposed in the seal substrate to pass through the seal substrate 5 in the thickness direction (predetermined direction) of the seal substrate 5. The through hole 55 communicates with the recessed portion (accommodation space) 51.

The through hole 55 has a transverse section in the shape of a circle across the Z-axis directional total length of the through hole 55. The diameter of the through hole 55 gradually decreases toward the recessed portion 51. That is, the area of the transverse section of the through hole 55 gradually decreases toward the recessed portion 51. The ratio D1/D2 of the diameter D1 of the upper face opening of the through hole 55 to the diameter D2 of the lower face opening of the through hole 55 is preferably 4 to 100 and more preferably 8 to 35. Accordingly, as will be described below, it is possible to stably arrange a spherical seal material 8a in the through hole 55.

The diameter D1 of the upper face opening of the through hole 55 is not particularly limited and, for example, is preferably greater than or equal to 200 μm and less than or equal to 500 μm and more preferably greater than or equal to 250 μm and less than or equal to 350 μm. The diameter D2 of the lower face opening of the through hole 55 is not particularly limited and, for example, is preferably greater than or equal to 5 μm and less than or equal to 50 μm and more preferably greater than or equal to 10 μm and less than or equal to 30 μm.

A material constituting the seal substrate 5 is not particularly limited provided that the material can exhibit a function such as the one described above. For example, a silicon material or a glass material can be exemplarily used.

The melting point (softening point) T₅ of the seal substrate 5 is not particularly limited and, for example, is preferably greater than or equal to 1000° C. and more preferably greater than or equal to 1100° C.

The through hole 55 is filled with the seal material 8 as illustrated in FIG. 11. Accordingly, the recessed portion (accommodation space) 51 is sealed in an airtight manner.

A melting point T₃ of the seal material 8 (Tb) is lower than the melting points or the softening points of the material constituting the supportive substrate 2 and the material constituting the seal substrate 5. The melting point T₃ is preferably greater than or equal to 200° C. and less than or equal to 400° C. and more preferably greater than or equal to 270° C. and less than or equal to 380° C.

The difference Tx of the melting point T₃ of the seal material 8 with respect to the melting point T₂ of the supportive substrate 2 or with respect to the melting point T₅ of the seal substrate 5 is preferably greater than or equal to 20° C. and less than or equal to 700° C. and more preferably greater than or equal to 50° C. and less than or equal to 660° C. Accordingly, the recessed portion (accommodation space) 51 can be effectively sealed.

There is a possibility that the seal material 8 is melted when the difference Tx is below the lower limit and when a heating time (bonding time) is comparatively increased in a below-described bonding step. Meanwhile, when the difference Tx is above the upper limit, it is difficult to select materials that constitute the seal material 8, the supportive substrate 2, and the seal substrate 5.

A material constituting the seal material 8 is not particularly limited. For example, a metal material such as an Au—Ge alloy and an Au—Sn alloy or a glass material having a low melting point can be used.

### Method for Manufacturing Physical Quantity Sensor

Next, a method for manufacturing the physical quantity sensor according to the present embodiment will be described.

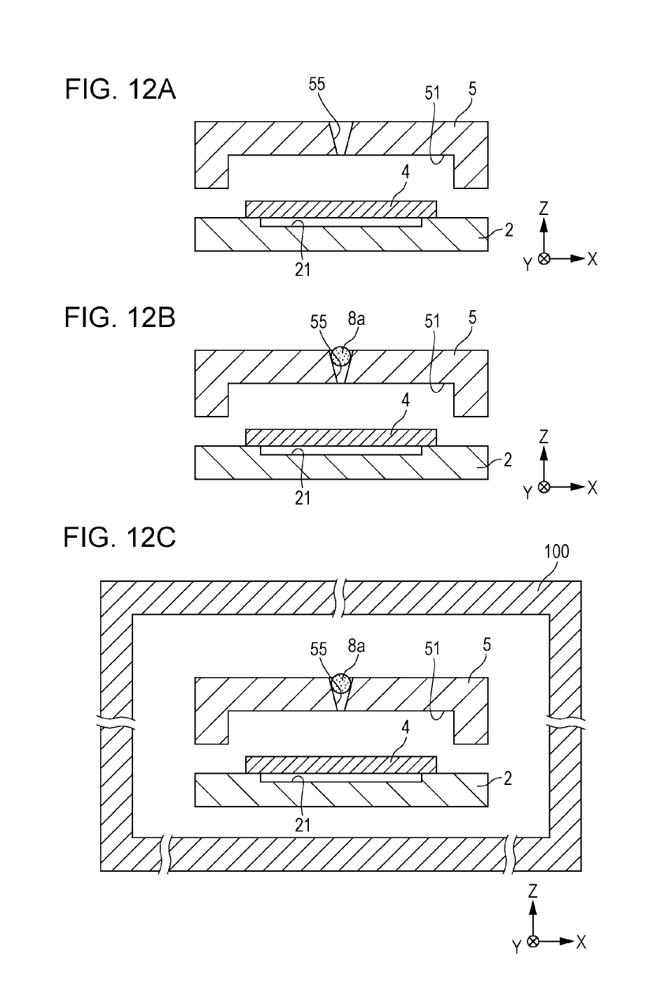

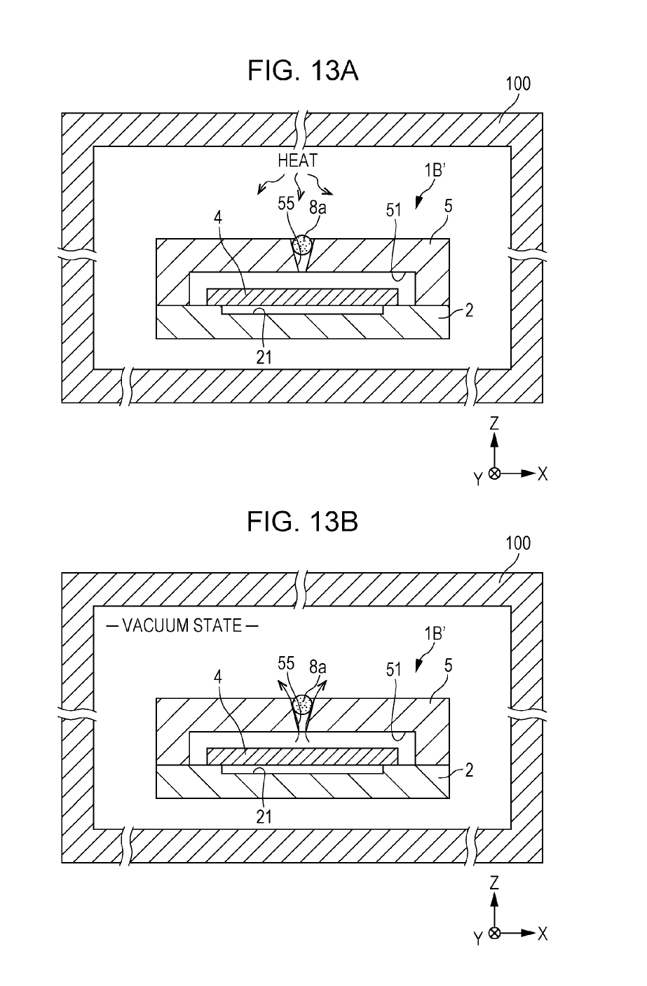

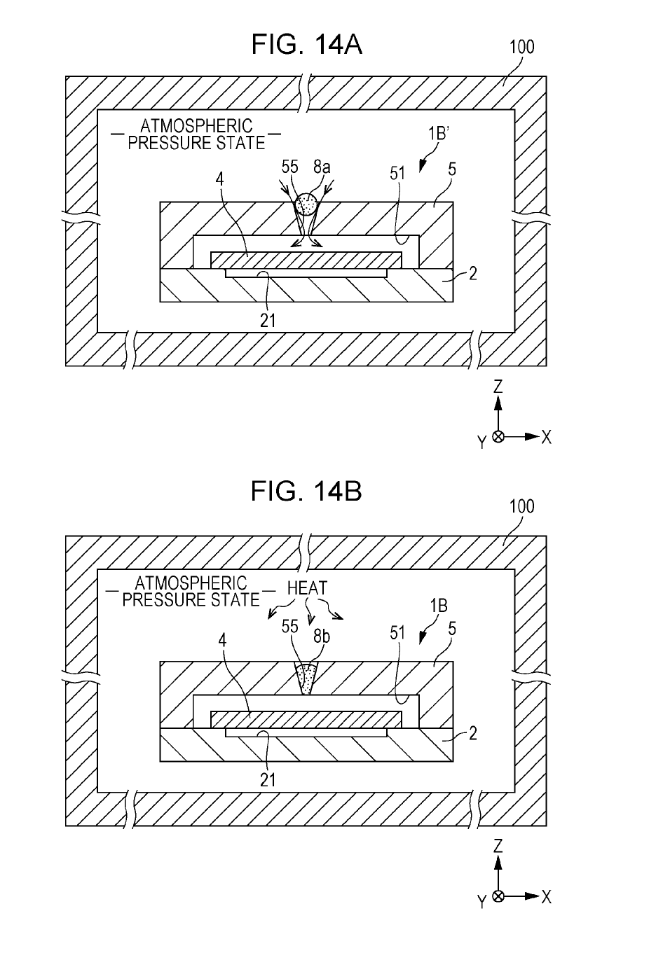

FIGS. 12A to 12C are sectional views for describing the method for manufacturing the physical quantity sensor according to the present embodiment: FIG. 12A is a diagram illustrating a preparing step, FIG. 12B is a diagram illustrating an arranging step, and FIG. 12C is a diagram illustrating a state where each substrate arranged is inserted into a chamber. FIGS. 13A and 13B are sectional views for describing the method for manufacturing the physical quantity sensor according to the present embodiment: FIG. 13A is a diagram illustrating a bonding step, and FIG. 13B is a diagram illustrating a pressure adjusting step (in the vacuum state). FIGS. 14A and 14B are sectional views for describing the method for manufacturing the physical quantity sensor according to the present embodiment: FIG. 14A is a diagram illustrating a pressure adjusting step (in the atmospheric pressure state), and FIG. 14B is a diagram illustrating a sealing step.

The method for manufacturing the physical quantity sensor according to the present embodiment includes [1] a preparing step, [2] an arranging step, [3] a bonding step, [4] a pressure adjusting step, and [5] a sealing step.

An example will be provided in the description below, in which the supportive substrate 2 is configured of a glass material that includes alkali metal ions and in which the seal substrate 5 is configured of a silicon material.

The acceleration sensor element 4 can be formed through a known method, and thus the formation thereof will not be described herein.

### [1] Preparing Step

First, as illustrated in FIG. 12A, the supportive substrate 2 where the acceleration sensor element 4 is disposed on the upper face thereof and the seal substrate 5 are prepared.

The hollow portion 21 of the supportive substrate 2, the recessed portion 51 of the seal substrate 5, and the through hole 55 are formed through etching.

A method for the etching is not particularly limited. For example, a combination of one or two or more of physical etching such as plasma etching, reactive ion etching, beam etching, and light-assisted etching, chemical etching such as wet etching, and the like can be used.

### [2] Arranging Step

Next, as illustrated in FIG. 12B, the spherical seal material 8a which is melted to the seal material 8 is arranged in the through hole 55. The outside diameter (maximum outside diameter) of the seal material 8a is greater than the diameter D2 of the lower face opening of the through hole 55 and is less than the diameter D1 of the upper face opening of the through hole 55. Accordingly, the seal material 8a can be arranged in the through hole 55 (hereinafter, this state will be referred to as “arranged state”).

The through hole 55, as described above, has a diameter that gradually decreases downward. Accordingly, in the arranged state, the seal material 8a stays at the part where the diameter of the seal material 8a matches the diameter of the through hole 55. Thus, a Z-axis directional movement of the seal material 8a in the through hole 55 is controlled. Furthermore, an XY-plane directional movement of the seal material 8a can also be controlled because the seal material 8a stays at the part where the diameter of the seal material 8a matches the diameter of the through hole 55. Accordingly, it is possible to arrange the seal material 8a still more stably in the through hole 55.

The outside diameter of such a seal material 8a is preferably greater than or equal to 100 μm and less than or equal to 500 μm and more preferably greater than or equal to 150 μm and less than or equal to 300 μm.

### [3] Bonding Step

Next, as illustrated in FIG. 12C, in the state where the seal material 8a is arranged in the through hole 55, the seal substrate 5 is arranged on the upper face of the supportive substrate 2 such that the acceleration sensor element 4 is accommodated in the recessed portion 51 (hereinafter, this state will be referred to as “physical quantity sensor 1B′”). The physical quantity sensor 1B′ is put into the chamber 100. The seal material 8a may be arranged in the through hole 55 after the seal substrate 5 is arranged on the upper face of the supportive substrate 2.

The upper face of the supportive substrate 2 and the lower face of the seal substrate 5 are bonded together through anodic bonding as illustrated in FIG. 13A.

The temperature inside the chamber 100 in the anodic bonding, that is, the temperature Ta of the physical quantity sensor 1B′ at the time of the anodic bonding is lower than the melting point T₃ of the seal material 8a. The temperature Ta is preferably greater than or equal to 150° C. and less than or equal to 380° C. and more preferably greater than or equal to 250° C. and less than or equal to 360° C. Accordingly, it is possible to prevent the seal material 8a from being melted to seal the recessed portion 51 when anodic bonding is performed in the state where the seal material 8a is arranged in the through hole 55.

In the bonding step, when the temperature Ta is below the lower limit, the bonding strength between the supportive substrate 2 and the seal substrate 5 may not be sufficient. When the temperature Ta is above the upper limit, the seal material 8a may be softened to seal the recessed portion 51.

A difference Ty between the temperature Ta of the physical quantity sensor 1B and the melting point T₃ of the seal material 8a at the time of the anodic bonding is preferably greater than or equal to 20° C. and less than or equal to 100° C. and more preferably greater than or equal to 50° C. and less than or equal to 80° C. By setting the difference Ty within the above numerical range, the present manufacturing step has excellent producibility.

There is a possibility that the seal material 8a is melted in the bonding step when the difference Ty is below the lower limit. Meanwhile, when the difference Ty is above the upper limit, a comparatively long time tends to be taken to increase the temperature inside the chamber 100 from the temperature Ta inside the chamber 100 in the bonding step to the melting point T₃ in the below-described sealing step.

The inside of the chamber 100 is maintained at the temperature Ta or higher until the pressure adjusting step is completed.

### [4] Pressure Adjusting Step

Next, as illustrated in FIG. 13B, a vacuum is created in the chamber 100 by using a vacuum pump. At this time, as illustrated by arrows in FIG. 13B, the air in the recessed portion 51 is discharged outside the recessed portion 51 through a minute gap between the seal material 8a and the inside face of the through hole 55. Accordingly, the inside of the recessed portion 51 becomes the vacuum state. In the present specification, “vacuum state” means the state where pressure is less than or equal to 10 Pa.

First after the inside of the recessed portion 51 is set to the vacuum state, for example, air or an inert gas such as nitrogen, argon, helium, and neon is injected into the chamber 100, and the pressure inside the chamber 100 is set to the atmospheric pressure state. Accordingly, as illustrated by arrows in FIG. 14A, air (inert gas) flows into the recessed portion 51 through a minute gap between the seal material 8a and the inside face of the through hole 55, and the inside of the recessed portion 51 becomes the atmospheric pressure state.

The inside of the recessed portion 51 is set to have atmospheric pressure in the pressure adjusting step of the present embodiment. However, the invention also includes setting the pressure inside the recessed portion 51 after the pressure adjusting step to a decreased pressure state where pressure is lower than atmospheric pressure. The decreased pressure state preferably has a pressure greater than or equal to 0.3×10⁵ Pa and less than or equal to 1×10⁵ Pa and more preferably greater than or equal to 0.5×10⁵ Pa and less than or equal to 0.8×10⁵ Pa. When the recessed portion 51 is sealed in such a decreased pressure state, damping (vibration damping force) having an appropriate magnitude acts in the acceleration sensor element 4 at the time of driving the acceleration sensor element 4, and in consequence, occurrence of unnecessary vibration can be prevented. Thus, it is possible to increase the detection sensitivity of the acceleration sensor element 4.

### [5] Sealing Step

Next, as illustrated in FIG. 14B, the inside of the chamber 100 is heated, and the seal material 8a is melted by setting the temperature inside the chamber 100 from the temperature Ta to the temperature Tc that is greater than or equal to the melting point T₃ of the seal material 8a. Accordingly, the seal material 8a that is melted to a liquid form (hereinafter, the liquid seal material 8a will be referred to as “seal material 8b”) adheres tightly to the inside face of the through hole 55 across the whole circumference of the through hole 55. Thus, the space in the recessed portion 51 and the space outside the recessed portion 51 are separated by the seal material 8b. In consequence, the recessed portion 51 is sealed in an airtight manner in the atmospheric pressure state.

The inside of the chamber 100, at this time, is maintained at the temperature Ta after the bonding step as described above. Accordingly, the temperature inside the chamber 100 may be increased by the difference between the temperature Ta and the temperature Tc. Thus, it is possible to melt the seal material 8a in a comparatively short time.

The seal material 8b has comparatively high surface tension and easily stays in the through hole 55 when a metal material is used as the seal material 8. Therefore, it is possible to prevent the seal material 8b from flowing into the recessed portion 51 from the lower face opening of the through hole 55.

The temperature To in the sealing step is higher than or equal to the melting point T₃ of the seal material 8 and lower than the melting point T₂ of the supportive substrate 2 and the melting point T₅ of the seal substrate 5. Accordingly, it is possible to melt the seal material 8a, and it is also possible to prevent the supportive substrate 2 and the seal substrate 5 from being thermally deformed.

The viscosity of the seal material 8b is preferably high to a certain extent and, specifically, is preferably greater than or equal to 1×10⁻³ Pa·s and more preferably greater than or equal to 3×10⁻³ Pa·s. Accordingly, it is possible to prevent the seal material 8b more effectively from flowing into the recessed portion 51 from the lower face opening of the through hole 55.

The diameter of the lower face opening of the through hole 55 is sufficiently small as described above. Accordingly, it is possible to prevent the seal material 8b still more effectively from flowing into the recessed portion 51 along with the above description.

Last, the seal material 8b is congealed by, for example, returning the temperature thereof to room temperature. Accordingly, the recessed portion 51 is sealed by the seal material 8 (refer to FIG. 11).

According to the invention, as described thus far, the recessed portion 51 can be sealed through a simple method of filling the through hole 55 with the seal material 8. Accordingly, it is possible to omit a step of deforming a substrate such that a groove is crushed as in “JP-A-2010-107325”. Thus, it is possible to seal the recessed portion without deforming the supportive substrate 2. Thus, the physical quantity sensor that is obtained through the present manufacturing method has excellent dimensional accuracy and high reliability.

The bonding step and the sealing step can be performed in the same chamber 100 by arranging the seal material 8a in the through hole 55 before the bonding step and maintaining the arranged state because the temperature Ta inside the chamber 100 in the bonding step is lower than the melting point T₃ of the seal material 8. Accordingly, it is possible to obtain the physical quantity sensor 1B once the physical quantity sensor 1B′ is put into the chamber 100 in the arranged state, without taking the physical quantity sensor 1B′ out of the chamber 100 and putting the physical quantity sensor 1B′ into the chamber 100 anymore. Thus, the present manufacturing method is simplified and has excellent producibility.

Furthermore, it is possible to effectively prevent or suppress influence on the physical quantity sensor 1B′ due to repeated heating and cooling of the physical quantity sensor 1B′ (for example, a crack and the like occurring in each substrate) because the number of times of taking the physical quantity sensor 1B′ out of the chamber 100 and putting the physical quantity sensor 1B′ into the chamber 100 can be decreased. Thus, according to the invention, it is possible to obtain the physical quantity sensor 1B that has exceptionally high reliability.

It is also possible to collectively obtain a plurality of physical quantity sensors 1B by inserting a plurality of physical quantity sensors 1B′ collectively into the chamber 100.

### Fourth Embodiment

Next, a fourth embodiment of a method for manufacturing a physical quantity sensor and the physical quantity sensor will be described.

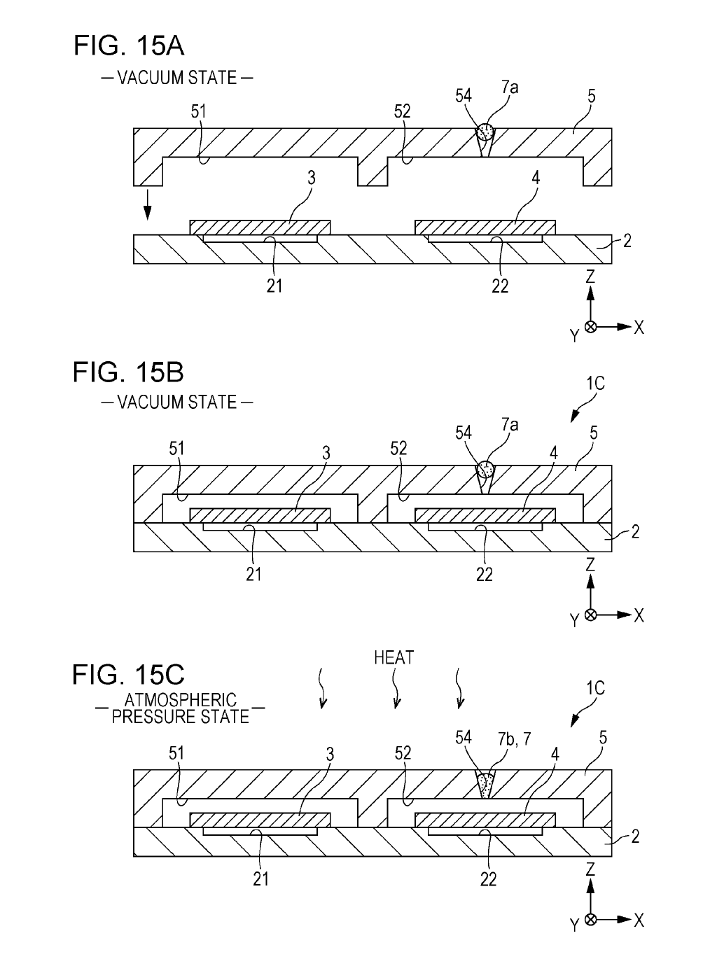

FIGS. 15A to 15C are sectional views for describing the method for manufacturing the physical quantity sensor according to the present embodiment: FIG. 15A is a diagram illustrating a first pressure adjusting step, FIG. 15B is a diagram illustrating a bonding step, and FIG. 15C is a diagram illustrating a sealing step.

Hereinafter, the fourth embodiment of the method for manufacturing the physical quantity sensor and the physical quantity sensor will be described with reference to FIGS. 15A to 15C with focus on the differences with respect to the above first embodiment, in which the same parts are not described.

The fourth embodiment is substantially the same as the first embodiment except that the seal substrate 5 has a different configuration.

In a physical quantity sensor 1C, as illustrated in FIGS. 15A to 15C, the through hole 53 of the seal substrate is omitted, and only the through hole 54 is disposed. This point is a main difference with respect to the first embodiment.

Specifically, the physical quantity sensor 1C is provided with the supportive substrate 2 in which the acceleration sensor element (first sensor element) 4 and the gyrosensor element (second sensor element) 3 are arranged, the seal substrate 5 that is bonded to the supportive substrate 2, forms the recessed portion (first accommodation space) 52 and the recessed portion (second accommodation space) 51 between the supportive substrate 2 and the seal substrate 5, and includes the through hole 54 which reaches the recessed portion (first accommodation space) 52, and the seal material 7 that seals the through hole 54.

Hereinafter, a method for manufacturing the physical quantity sensor 1C will be described. The method for manufacturing the physical quantity sensor 1C according to the present embodiment includes [1] a preparing step, [2] a first pressure adjusting step, [3] a bonding step, [4] a second pressure adjusting step, and [5] a sealing step.

### [1] Preparing Step

First, the supportive substrate 2 where each of the sensor elements 3 and 4 is disposed on the upper face thereof and the seal substrate 5 in which only the through hole 54 is formed are prepared. In the present embodiment, the spherical seal material 7a is arranged in advance in the through hole 54.

### [2] First Pressure Adjusting Step

Next, as illustrated in FIG. 15A, in the present embodiment, the atmosphere of the supportive substrate 2 and the seal substrate 5 is set to the vacuum state before bonding of the supportive substrate 2 and the seal substrate 5 together. Accordingly, the inside of the recessed portion 51 becomes the vacuum state.

### [3] Bonding Step

Next, as illustrated in FIG. 15B, the supportive substrate 2 and the seal substrate 5 are bonded together in the same manner as the bonding step in the first embodiment while the inside of the recessed portion 51 is in the vacuum state. Accordingly, the recessed portion (second accommodation space) 51 is sealed in an airtight manner in the vacuum state. A through hole reaching the recessed portion 51 is not formed in the recessed portion 51, and, for example, there is no possibility that the vacuum state inside the recessed portion 51 is deteriorated due to failure of sealing a through hole. Thus, it is possible to seal the recessed portion (second accommodation space) 51 in an airtight manner more stably in comparison with the case where a through hole reaching the recessed portion 51 is formed.

Although the inside of the chamber is heated in the bonding step, the temperature inside the chamber (temperatures of the supportive substrate 2 and the seal substrate 5) is lower than the melting point of the seal material 7a. Accordingly, it is possible to prevent the seal material 7a from being melted in the bonding step. Thus, it is possible to prevent the recessed portion 52 from being unintentionally sealed in the bonding step.

### [4] Second Pressure Adjusting Step

Next, as illustrated in FIG. 15C, the atmosphere of the supportive substrate 2 and the seal substrate 5 is set to the atmospheric pressure state from the vacuum state in the same manner as the second pressure adjusting step of the first embodiment.

### [5] Sealing Step

The spherical seal material 7a in the through hole 54 is melted to the seal material 7b in the same manner as the second sealing step of the first embodiment as illustrated in FIG. 15C. Afterward, the seal material 7b is congealed, and the through hole 54 is filled with the seal material 7. Accordingly, the recessed portion 52 (first accommodation space) is sealed in the atmospheric pressure state.

As such, the physical quantity sensor 1C according to the present embodiment is characterized in that the physical quantity sensor 1C is provided with the supportive substrate 2 in which the acceleration sensor element (first sensor element) 4 and the gyrosensor element (second sensor element) 3 are arranged, the seal substrate 5 that is bonded to the supportive substrate 2, forms the recessed portion (first accommodation space) 52 and the recessed portion (second accommodation space) 51 between the supportive substrate 2 and the seal substrate 5, and includes the through hole 54 which reaches the recessed portion (first accommodation space) 52, and the seal material 7 that seals the through hole 54, in which the acceleration sensor element 4 (first sensor element) is accommodated in the recessed portion (first accommodation space) 52 and in which the melting point of the seal material 7a is higher than the temperature required to bond the supportive substrate 2 and the seal substrate 5 together.

The first sealing step of the first embodiment is omitted in the present embodiment because a through hole reaching the recessed portion (second accommodation space) 51 is not formed. Thus, the producibility of the physical quantity sensor 1C can be increased. Furthermore, in comparison with the case where a through hole reaching the recessed portion (second accommodation space) 51 is formed, the recessed portion (second accommodation space) 51 can be sealed more stably in an airtight manner.

The spherical seal material 7a is arranged in advance in the through hole 54 in the preparing step of the present embodiment. However, the invention is not limited to this. The seal material 7a may be arranged in the through hole 54 in any of steps before the sealing step is performed.

### Electronic Device

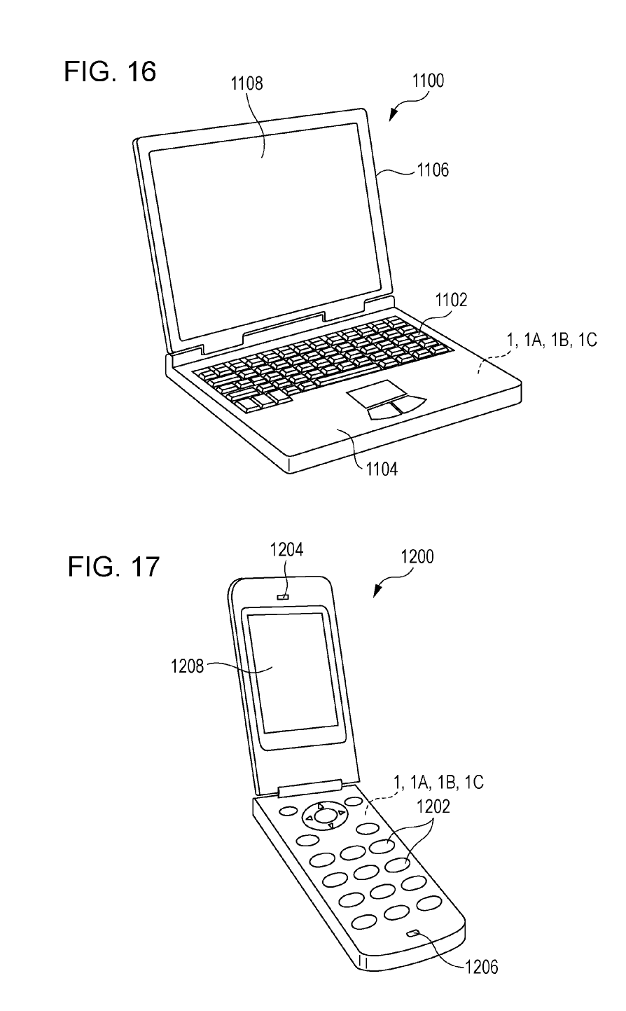

Next, an electronic device to which any one of the physical quantity sensors 1, 1A, 1B, and 1C according to the present embodiment is applied will be described in detail on the basis of FIG. 16 to FIG. 18.

FIG. 16 is a perspective view illustrating a configuration of a mobile (or notebook) personal computer to which the electronic device provided with the physical quantity sensor according to the present embodiment is applied. In FIG. 16, a personal computer 1100 is configured of a main body portion 1104 and a display unit 1106. The main body portion 1104 is provided with a keyboard 1102, and the display unit 1106 is provided with a display portion 1108. The display unit 1106 is rotatably supported by the main body portion 1104 through a hinge structure portion. In such a personal computer 1100, any one of the physical quantity sensors 1, 1A, 1B, and 1C that functions as an angular velocity detector is incorporated.

FIG. 17 is a perspective view illustrating a configuration of a mobile phone (including a PHS) to which the electronic device provided with the physical quantity sensor according to the present embodiment is applied. In FIG. 17, a mobile phone 1200 is provided with a plurality of operating buttons 1202, an earpiece 1204, and a mouthpiece 1206, and a display portion 1208 is arranged between the operating buttons 1202 and the earpiece 1204. In such a mobile phone 1200, any one of the physical quantity sensors 1, 1A, 1B, and 1C that functions as an angular velocity detector is incorporated.

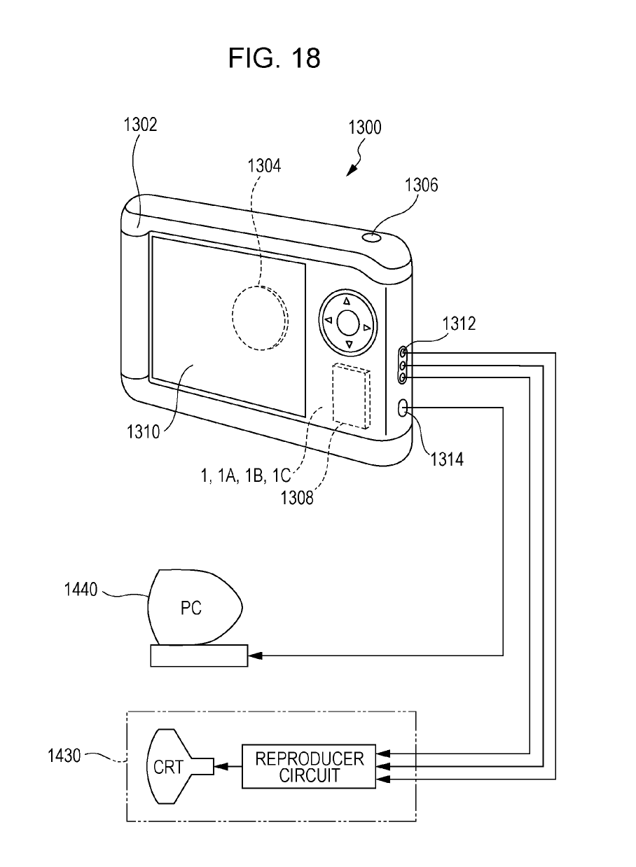

FIG. 18 is a perspective view illustrating a configuration of a digital still camera to which the electronic device provided with the physical quantity sensor according to the present embodiment is applied. In FIG. 18, connections to external devices are also simply illustrated. A typical camera sensitizes a silver salt photographic film by using a light image of a subject. Meanwhile, a digital still camera 1300 performs photoelectric conversion on a light image of a subject by using a capturing element such as a charge coupled device (CCD) and generates a capture signal (image signal).

A display portion is disposed on the rear face of a case (body) 1302 of the digital still camera 1300 and is configured to perform displaying on the basis of the capture signal from the CCD. A display portion 1310 functions as a finder that displays a subject as an electronic image.

A light-receiving unit 1304 that includes an optical lens (optical capturing system), a CCD, and the like is disposed on the front face side (rear face side in FIG. 18) of the case 1302.

When a capturer confirms an image of a subject displayed on the display portion and presses a shutter button 1306, a capture signal of the CCD at that time is transmitted to a memory 1308 and is stored thereon.

In the digital still camera 1300, a video signal output terminal 1312 and a data communication input-output terminal 1314 are disposed on a side face of the case 1302.

As illustrated in FIG. 18, when necessary, a television monitor 1430 is connected to the video signal output terminal 1312, and a personal computer 1440 is connected to the data communication input-output terminal 1314. By a predetermined operation, the capture signal stored on the memory 1308 is configured to be output to the television monitor 1430 or to the personal computer 1440.

In such a digital still camera 1300, any one of the physical quantity sensors 1, 1A, 1B, and 1C that functions as an angular velocity detector is incorporated.

The electronic device provided with the physical quantity sensor according to the present embodiment, in addition to the personal computer (mobile personal computer) in FIG. 16, the mobile phone in FIG. 17, and the digital still camera in FIG. 18, can be applied to, for example, an ink jet discharging apparatus (for example, an ink jet printer), a laptop personal computer, a television, a video camera, a video tape recorder, a car navigation device, a pager, an electronic organizer (includes a communication function), an electronic dictionary, an electronic calculator, an electronic gaming device, a word processor, a workstation, a television telephone, a security television monitor, an electronic binocular, a POS terminal, a medical device (for example, an electronic thermometer, a sphygmomanometer, a blood glucose meter, an electrocardiograph, an ultrasonic diagnostic device, and an electronic endoscope), a fishfinder, various measuring devices, instruments (for example, instruments of a vehicle, an aircraft, and a ship), and a flight simulator.

### Moving Body

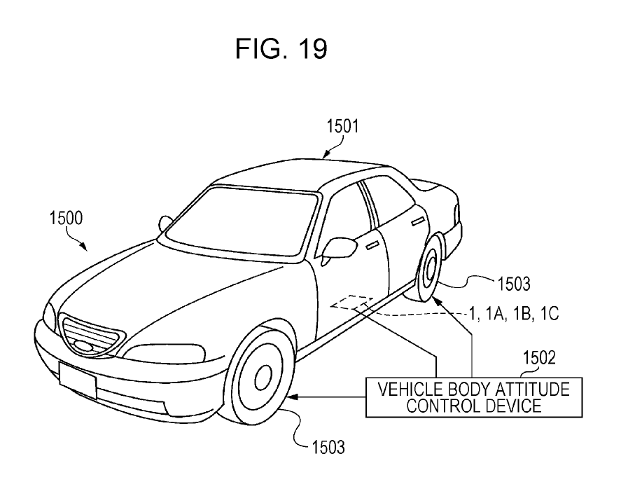

Next, a moving body to which the physical quantity sensor according to the present embodiment is applied will be described in detail on the basis of FIG. 19.

FIG. 19 is a perspective view illustrating a configuration of an automobile to which a moving body provided with the physical quantity sensor according to the present embodiment is applied. In an automobile 1500, any one of the physical quantity sensors 1, 1A, 1B, and 1C that functions as an angular velocity detector is incorporated. Any one of the physical quantity sensors 1, 1A, 1B, and 1C can detect the attitude of a vehicle body 1501. A signal from any one of the physical quantity sensors 1, 1A, 1B, and 1C is supplied to a vehicle body attitude control device 1502. The vehicle body attitude control device 1502 detects the attitude of the vehicle body 1501 on the basis of the signal and can control suspension softness or can control brakes for individual wheels 1503 according to the detection result. In addition, such an attitude control can be used in a biped robot and in a radio-controlled helicopter. As described thus far, any one of the physical quantity sensors 1, 1A, 1B, and 1C is incorporated into moving bodies so as to realize the attitude control for various moving bodies.

While descriptions are thus far provided of the method for manufacturing the physical quantity sensor, the physical quantity sensor, the electronic device, and the moving body of the invention on the basis of the illustrated embodiments, the invention is not limited to the embodiments. Each unit constituting the physical quantity sensor can be substituted by an arbitrary configuration that can exhibit the same function. In addition, other arbitrary configurations may be added thereto.

The method for manufacturing the physical quantity sensor, the physical quantity sensor, the electronic device, and the moving body of the invention may be a combination of two or more arbitrary configurations (features) of each embodiment above.

The seal materials arranged in each through hole are configured of the same material in the first embodiment to the third embodiment. However, the invention is not limited to this, and the seal materials may be configured of different materials.

The arranging step may be performed in the chamber, and the bonding step may also be performed in the chamber.

The through holes in each embodiment have widths (diameters) that gradually decrease across the total lengths thereof in the depth direction. However, the invention is not limited to this, and the widths (diameters) may decrease in a stepwise manner or may be partially constant.

One or two recessed portions are disposed in each embodiment. However, the invention is not limited to this. Three or more recessed portions may be formed, and sensor elements may be arranged in each of the recessed portions.

The seal materials are melted by increasing the temperature inside the chamber in each embodiment. However, the invention is not limited to this. For example, the seal materials may be melted by irradiating the seal materials with a laser.

The first recessed portion is sealed earlier than the second recessed portion in each embodiment. However, the invention is not limited to this, and the second recessed portion may be sealed first.

Various modification examples are considered in addition to the above contents. Hereinafter, modification examples will be described.

### First Modification Example

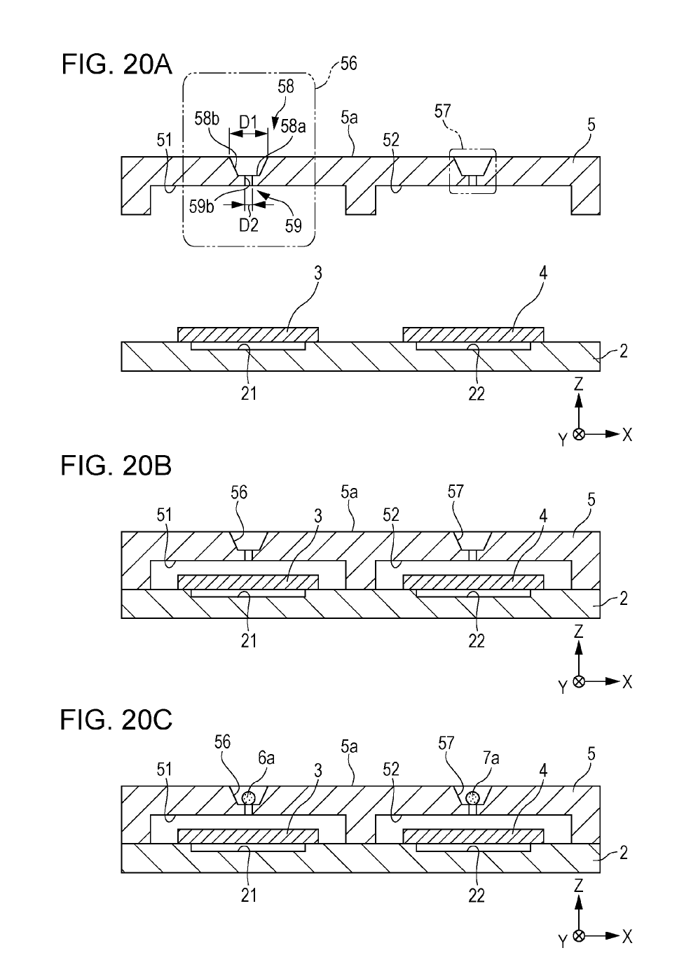

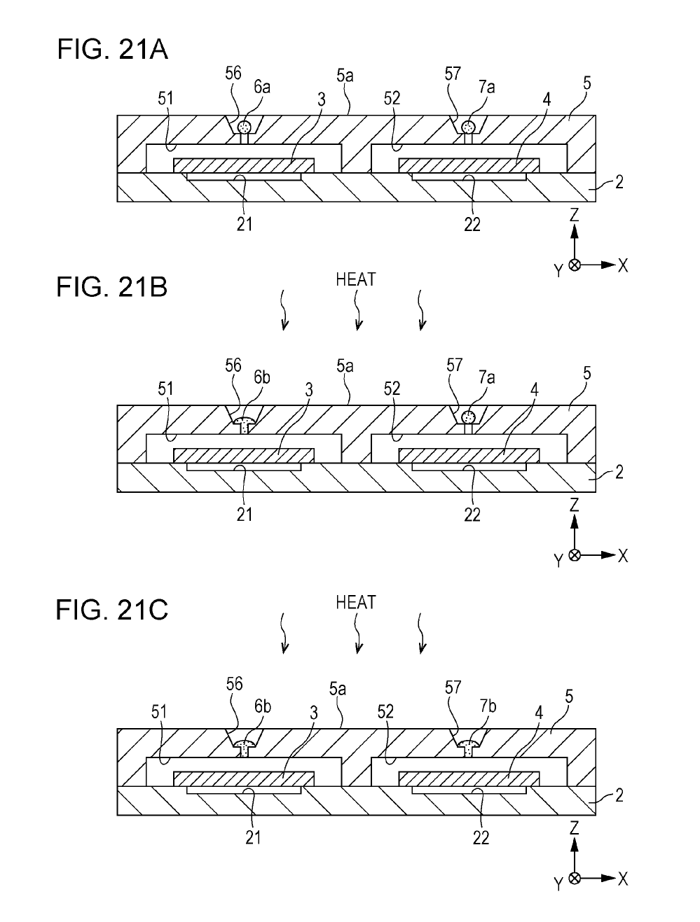

FIGS. 20A to 20C are diagrams corresponding to FIGS. 4A to 4C. FIGS. 21A and 21B are diagrams corresponding to FIGS. 5A to 5C. FIG. 21C is a diagram corresponding to FIG. 6. Each of these drawings is a sectional view for describing a method for manufacturing a physical quantity sensor according to a first modification example.

Specifically, FIG. 20A is a diagram illustrating a preparing step, FIG. 20B is a diagram illustrating a bonding step, and FIG. 20C is a diagram illustrating an arranging step. FIG. 21A is a diagram illustrating a first pressure adjusting step, FIG. 21B is a diagram illustrating a first sealing step, and FIG. 21C is a diagram illustrating a second sealing step.

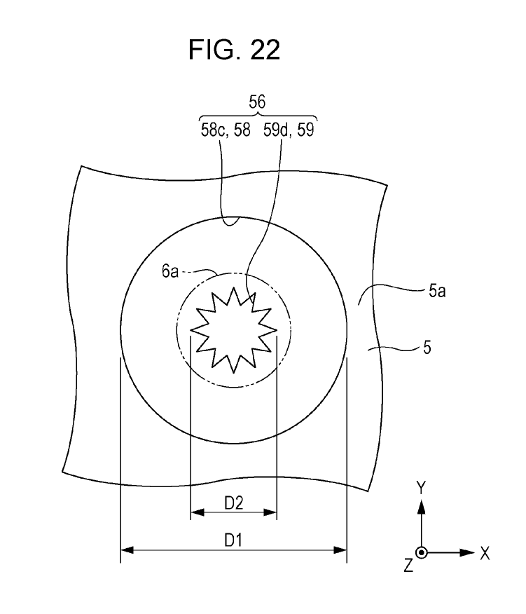

FIG. 22 is a diagram of a through hole viewed from the Z direction and is a schematic plan view illustrating a state of a through hole that is disposed in a seal substrate. Although described in detail below, a through hole 56 includes a first hole portion 58 and a second hole portion 59, and an upper face opening 58c of the first hole portion 58 and a lower face opening 59d of the second hole portion are illustrated in FIG. 22. The seal material 6a is illustrated by a double-dot chain line in FIG. 22. A view from the Z direction will be referred to as a plan view.

In the present modification example, the shapes of through holes 56 and 57 disposed in the seal substrate 5 are different from the shapes of the through holes 53 and 54 according to the first embodiment. Other configurations in the present modification example are the same as those in the first embodiment. Hereinafter, with reference to FIG. 20A to FIG. 22, the method for manufacturing the physical quantity sensor according to the present modification example will be described with focus on the differences with respect to the first embodiment. The same constituent as in the first embodiment will be designated by the same reference sign, and a duplicate description thereof will not be provided.

The method for manufacturing the physical quantity sensor according to the present modification example includes [1] a preparing step, [2] a bonding step, [3] an arranging step, [4] a first pressure adjusting step, [5] a first sealing step, [6] a second pressure adjusting step, and [7] a second sealing step. That is, the method for manufacturing the physical quantity sensor according to the present modification example includes the same steps as the method for manufacturing the physical quantity sensor according to the first embodiment.

In the preparing step, as illustrated in FIG. 20A, the supportive substrate 2 where the gyrosensor element 3 and the acceleration sensor element 4 are disposed on the upper face thereof and the seal substrate 5 in which the through holes 56 and 57 are disposed are prepared. The through hole 56 communicates with the recessed portion 51, and the through hole 57 communicates with the recessed portion 52.

The through hole 56 and the through hole 57 have the same configuration (same shape). Thus, the through hole 56 will be representatively described hereinafter.

As illustrated in FIG. 20A and FIG. 22, the through hole 56 is configured to include the first hole portion 58 and the second hole portion 59. The first hole portion 58 is disposed on an outer face 5a of the seal substrate 5 (on the opposite side from the recessed portion 51), and the second hole portion 59 is disposed on the recessed portion 51 side of the seal substrate 5.

The first hole portion 58 includes a bottom face 58a and an inner wall face 58b and has a circular transverse section across the Z-axis directional total length thereof. The diameter of the first hole portion 58 gradually decreases toward the recessed portion 51. The diameter of the upper face opening 58c of the first hole portion 58 is D1 and has the same dimension as the diameter D1 of the upper face opening of the through hole 53 according to the first embodiment.

The second hole portion 59 includes an inner wall face 59b and provides a communication between the first hole portion 58 and the recessed portion 51. The second hole portion 59, in a plan view, is arranged inside the bottom face 58a of the first hole portion 58 and has a transverse section of a star polygon. The second hole portion 59 is formed such that at least a part of the inner wall face 59b is at an approximately right angle with respect to the bottom face 58a of the first hole portion 58. That is, the second hole portion 59 has a shape of a pillar of which the transverse section is a star polygon. The maximum dimension of the lower face opening 59d of the second hole portion 59 is D2 and is the same dimension as the diameter D2 of the lower face opening of the through hole 53 according to the first embodiment.

The second hole portion 59 has a transverse section of a star polygon as described above. In other words, the outline of the transverse section of the second hole portion 59 is a polygon formed by a polygonal line, and the area of the inner wall face 59b is large in comparison with the case where the outline of the transverse section is a circle or a polygon (for example, in comparison with the first embodiment). Furthermore, in other words, the second hole portion 59 has a shape capable of having a large area of the inner wall face 59b.

The second hole portion 59 may desirably have a shape capable of having a large area of the inner wall face 59b and, for example, may have a configuration in which roughness, recesses, protrusions, and the like are formed on the inner wall face 59b.

Such a second hole portion 59 can be formed by etching the inner face (face on the opposite side from the outer face 5a) of the seal substrate 5 using a combination of one or two or more of physical etching such as plasma etching, reactive ion etching, beam etching, and light-assisted etching, chemical etching such as wet etching, and the like.

Furthermore, roughness, recesses, protrusions, and the like can be formed on the inner wall face 59b through a method of local deposition of a film such as ion beam deposition or through a method of local removal of a film such as blasting.

In the bonding step, as illustrated in FIG. 20B, the upper face of the supportive substrate 2 and the lower face of the seal substrate 5 are bonded together through anodic bonding. Accordingly, it is possible to bond the supportive substrate 2 and the seal substrate 5 together with high strength and air tightness.

In the arranging step, as illustrated in FIG. 20C, the spherical seal material 6a which is the seal material 6 is arranged inside the through hole 56, and the spherical seal material 7a which is the seal material 7 is arranged inside the through hole 57.

In the first pressure adjusting step, as illustrated in FIG. 21A, the atmosphere of the supportive substrate 2 and the seal substrate 5 is exhausted (deflated) and is set to the vacuum state (first atmosphere).

In the first sealing step, as illustrated in FIG. 21B, the inside of the chamber is heated, and the seal material 6a in the through hole 56 is melted by setting the temperature inside the chamber to be greater than or equal to the melting point T₆ of the seal material 6a.

Accordingly, the liquid seal material 6b covers the bottom face 58a of the through hole 56, and the second hole portion 59 of the through hole 56 is filled with the seal material 6b. Then, the seal material 6b is hardened, and the recessed portion 51 is sealed in an airtight manner in the vacuum state.

In the second pressure adjusting step, as illustrated in FIG. 21C, the pressure inside the chamber is set to the atmospheric pressure state (second state) where pressure is higher than the pressure in the vacuum state. In the second sealing step, the inside of the chamber is heated, and the seal material 7a in the through hole 57 is melted by setting the temperature inside the chamber to be greater than or equal to the melting point T₇ of the seal material 7a. Accordingly, the inside of the through hole 57 is filled with the liquid seal material 7b. Then, the seal material 7b is hardened, and the recessed portion 52 is sealed in an airtight manner in the atmospheric pressure state where pressure is higher than the pressure in the vacuum state.

The melting point T₇ of the seal material 7a is higher than the melting point T₆ of the seal material 6a. Thus, the seal material 6a may be melted to a liquid form in the second sealing step. At such a time, the liquid seal material 6b is drawn (hangs down) into the recessed portion due to the pressure difference between the pressure applied on the outer face 5a side of the seal substrate 5 (atmospheric pressure) and the pressure on the recessed portion 51 side of the seal substrate 5 (vacuum state) or due to the weight of the seal material 6a. This may cause the vacuum state (air tightness) of the recessed portion 51 to be deteriorated.

In the present modification example, the area of the inner wall face 59b of the second hole portion 59 is large, and the area of contact between the inner wall face 59b of the second hole portion 59 and the seal material 6a is large in comparison with the first embodiment. Thus, the fluid resistance of the liquid seal material 6b in the second sealing step is increased, and the liquid seal material 6b is unlikely to flow. Thus, in the present modification example, the liquid seal material 6b is unlikely to be drawn (hang down) into the recessed portion in comparison with the first embodiment, and it is possible to prevent the air tightness of the recessed portion 51 still more effectively from being deteriorated.

It is also possible to hinder the liquid seal material 6b from being drawn (hanging down) into the recessed portion 51 in the second sealing step by, for example, decreasing the diameter of the second hole portion 59. However, when the diameter of the second hole portion 59 is decreased, the atmosphere of the supportive substrate and the seal substrate 5 is unlikely to be exhausted (deflated) in the first pressure adjusting step.

The atmosphere of the supportive substrate 2 and the seal substrate 5 is easily exhausted (deflated) in the first pressure adjusting step when, for example, the diameter of the second hole portion 59 is increased. However, the liquid seal material 6b is easily drawn (hang down) into the recessed portion 51 in the second sealing step, and the air tightness of the recessed portion 51 is easily deteriorated.

In the present modification example, it is possible to hinder the liquid seal material 6b from being drawn (hanging down) into the recessed portion 51 in the second sealing step while securing the diameter of the second hole portion 59 in the degree to which exhaustion (deflation) is easily performed in the first pressure adjusting step by increasing the area of the inner wall face 59b of the second hole portion 59. Therefore, the present modification example can achieve the effect in which the vacuum state (first atmosphere) can be stably formed in the first pressure adjusting step in addition to the effect in which it is possible to prevent the air tightness of the recessed portion 51 from being deteriorated in the second sealing step.

### Second Modification Example

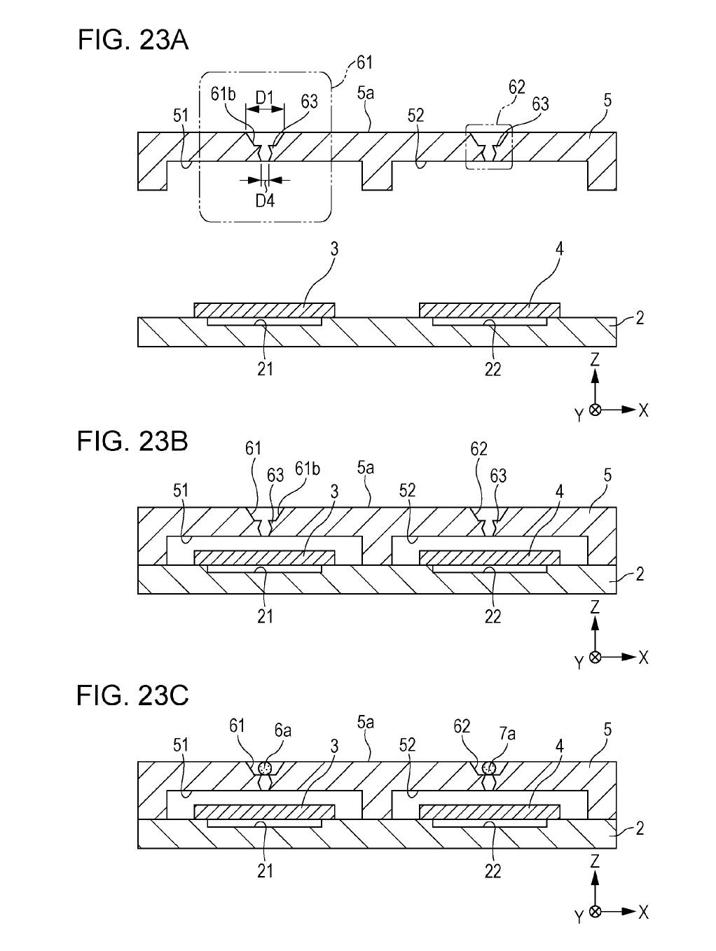

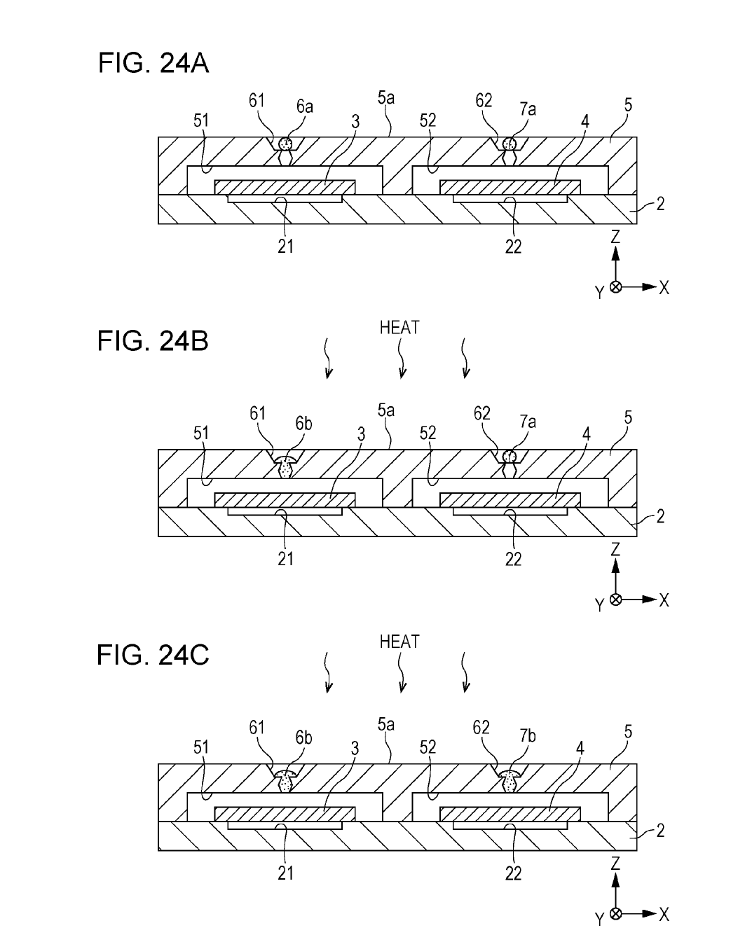

FIGS. 23A to 23C are diagrams corresponding to FIGS. 4A to 4C. FIGS. 24A and 24B are diagrams corresponding to FIGS. 5A to 5C. FIG. 24C is a diagram corresponding to FIG. 6. Each of these drawings is a sectional view for describing a method for manufacturing a physical quantity sensor according to a second modification example.

Specifically, FIG. 23A is a diagram illustrating a preparing step, FIG. 23B is a diagram illustrating a bonding step, and FIG. 23C is a diagram illustrating an arranging step. FIG. 24A is a diagram illustrating a first pressure adjusting step, FIG. 24B is a diagram illustrating a first sealing step, and FIG. 24C is a diagram illustrating a second sealing step.

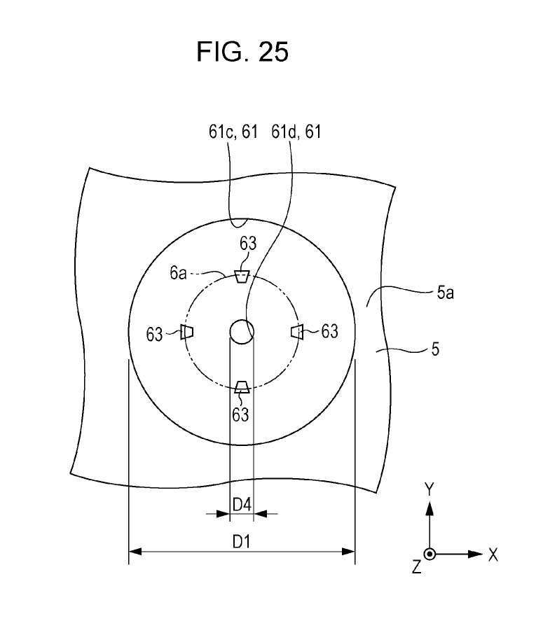

FIG. 25 is a diagram of a through hole viewed from the Z direction and is a schematic plan view illustrating a state of a through hole that is disposed in a seal substrate. Although described in detail below, a through hole 61 includes a plurality of protrusions 63, and the arranged state of the protrusions 63 is illustrated in FIG. 25. Furthermore, an upper face opening 61c of the through hole 61 and a lower face opening 61d of the through hole 61 are illustrated by solid lines, and the seal material 6a is illustrated by a double-dot chain line in FIG. 25.

In the present modification example, the shapes of through holes 61 and 62 disposed in the seal substrate 5 are different from the shapes of the through holes 53 and 54 according to the first embodiment. Other configurations in the present modification example are the same as those in the first embodiment. Hereinafter, with reference to FIG. 23A to FIG. 25, the method for manufacturing the physical quantity sensor according to the present modification example will be described with focus on the differences with respect to the first embodiment. The same constituent as in the first embodiment will be designated by the same reference sign, and a duplicate description thereof will not be provided.

The method for manufacturing the physical quantity sensor according to the present modification example includes [1] a preparing step, [2] a bonding step, [3] an arranging step, [4] a first pressure adjusting step, [5] a first sealing step, [6] a second pressure adjusting step, and [7] a second sealing step. That is, the method for manufacturing the physical quantity sensor according to the present modification example includes the same steps as the method for manufacturing the physical quantity sensor according to the first embodiment.

In the preparing step, as illustrated in FIG. 23A, the supportive substrate 2 where the gyrosensor element 3 and the acceleration sensor element 4 are disposed on the upper face thereof and the seal substrate 5 in which the through holes 61 and 62 are disposed are prepared. The through hole 61 communicates with the recessed portion 51, and the through hole 62 communicates with the recessed portion 52.

The through hole 61 and the through hole 62 have the same configuration (same shape). Thus, the through hole 61 will be representatively described hereinafter.

As illustrated in FIG. 23A and FIG. 25, the through hole 61 has a transverse section in the shape of a circle across the Z-axis directional total length of the through hole 55. The diameter of the through hole 61 gradually decreases toward the recessed portion 51. That is, the area of the transverse section of the through hole 61 gradually decreases toward the recessed portion 51. The diameter of the upper face opening 61c of the through hole 61 is D1 and has the same dimension as the diameter D1 of the upper face opening of the through hole 53 according to the first embodiment. The diameter of the lower face opening 61d of the through hole 61 is D4 and is less than the diameter D2 of the lower face opening of the through hole 53 according to the first embodiment. That is, the through hole 61 according to the present modification example has a narrow lower face opening 61d in comparison with the through hole 53 according to the first embodiment.

Four protrusions 63 are disposed on an inner wall face 61b of the through hole 61. The four protrusions 63 are arranged such that a line connecting one protrusion 63 and adjacent protrusions 63 forms a square in a plan view. That is, the four protrusions 63 are arranged at the vertices of a square that is inscribed in the inner wall face 61b.

The number of protrusions 63 disposed on the inner wall face 61b is not limited to four and may be more than four or may be less than four.

As such, the differences between the through hole according to the present modification example and the through hole 53 according to the first embodiment are that the lower face opening 61d of the through hole 61 is narrow in comparison with the first embodiment and that the protrusions 63 are disposed on the inner wall face 61b.

In the bonding step, as illustrated in FIG. 23B, the upper face of the supportive substrate 2 and the lower face of the seal substrate 5 are bonded together through anodic bonding. Accordingly, it is possible to bond the supportive substrate 2 and the seal substrate 5 together with high strength and air tightness.

In the arranging step, as illustrated in FIG. 23C, the spherical seal material 6a which is the seal material 6 is arranged inside the through hole 61, and the spherical seal material 7a which is the seal material 7 is arranged inside the through hole 62.

The seal material 6a is supported (held) by the protrusions 63. In consequence, a gap is formed between the inner wall face 61b of the through hole 61 and the seal material 6a. That is, the protrusions 63 have a role of forming a gap between the inner wall face 61b of the through hole 61 and the seal material 6a.

The protrusions 63 can be formed on the inner wall face 61b of the through hole 61 by, for example, etching the seal substrate 5 multiple times using a combination of one or two or more of physical etching such as plasma etching, reactive ion etching, beam etching, and light-assisted etching, chemical etching such as wet etching, and the like. The protrusions 63 can be formed on the inner wall face 61b of the through hole 61 through, for example, a method of local disposition of a film such as ion beam deposition.

In the first pressure adjusting step, as illustrated in FIG. 24A, the atmosphere of the supportive substrate 2 and the seal substrate 5 is exhausted (deflated) and is set to the vacuum state (first atmosphere). Since the protrusions 63 form a gap between the inner wall face 61b of the through hole 61 and the seal material 6a, the air in the recessed portion 51 is easily exhausted from the through hole 61 in comparison with the case where a gap is not formed between the inner wall face 61b and the seal material 6a. Thus, even though the lower face opening 61d of the through hole 61 is narrower than the lower face opening of the through hole 53 according to the first embodiment, the air in the recessed portion 51 can be smoothly exhausted from the through hole 61.

In the first sealing step, as illustrated in FIG. 24B, the inside of the chamber is heated, and the seal material 6a in the through hole 61 is melted by setting the temperature inside the chamber to be greater than or equal to the melting point T₆ of the seal material 6a. Accordingly, the liquid seal material 6b covers a part of the inner wall face 61b of the through hole 61, and the through hole 61 is filled with the seal material 6b. Then, the seal material 6b is hardened, and the recessed portion 51 is sealed in an airtight manner in the vacuum state.

In the second pressure adjusting step, as illustrated in FIG. 24C, the pressure inside the chamber is set to the atmospheric pressure state (second state) where pressure is higher than the pressure in the vacuum state. In the second sealing step, the inside of the chamber is heated, and the seal material 7a in the through hole 62 is melted by setting the temperature inside the chamber to be greater than or equal to the melting point T₇ of the seal material 7a. Accordingly, the inside of the through hole 62 is filled with the liquid seal material 7b. Then, the seal material 7b is hardened, and the recessed portion 52 is sealed in an airtight manner in the atmospheric pressure state where pressure is higher than the pressure in the vacuum state.

The melting point T₇ of the seal material 7a is higher than the melting point T₆ of the seal material 6a. Thus, the seal material 6a is melted to a liquid form in the second sealing step. The liquid seal material 6b is drawn (hangs down) into the recessed portion 51 due to the pressure difference between the pressure applied on the outer face 5a side of the seal substrate 5 (atmospheric pressure) and the pressure on the recessed portion 51 side of the seal substrate 5 (vacuum state) or due to the weight of the seal material 6a. This may cause the vacuum state (air tightness) of the recessed portion 51 to be deteriorated.

In the present modification example, the lower face opening 61d of the through hole 61 is narrower than the lower face opening of the through hole 53 according to the first embodiment. Thus, the liquid seal material 6b is unlikely to be drawn (hang down) into the recessed portion 51, and it is possible to suppress deterioration of the air tightness of the recessed portion 51. That is, in the present modification example, in comparison with the first embodiment, it is possible to prevent the liquid seal material 6b still more effectively from flowing into the recessed portion 51 in the second sealing step.

In the first embodiment, it is possible to hinder the liquid seal material 6b from being drawn (hanging down) into the recessed portion 51 in the second sealing step by, for example, narrowing the lower face opening of the through hole 53. However, a gap is not formed between the inner wall face 61b and the seal material 6a in the first embodiment. Thus, when the lower face opening of the through hole 53 is narrowed, the atmosphere of the supportive substrate 2 and the seal substrate 5 is unlikely to be exhausted (deflated) in the first pressure adjusting step.

In the present modification example, it is possible to smoothly exhaust (deflate) the air in the recessed portion 51 from the through hole 61 in the first pressure adjusting step even though the lower face opening 61d of the through hole 61 is narrowed, by disposing the protrusions 63 that form a gap between the inner wall face 61b of the through hole 61 and the seal material 6a. Furthermore, in the present modification example, the liquid seal material 6b to which the seal material 6a is melted in the second sealing step is unlikely to be drawn (hang down) into the recessed portion 51 by narrowing the lower face opening 61d of the through hole 61, and it is possible to suppress deterioration of the air tightness of the recessed portion 51.

The entire disclosure of Japanese Patent Application Nos. 2014-155930, filed Jul. 31, 2014; 2014-155933, filed Jul. 31, 2014 and 2014-236285, filed Nov. 21, 2014 are expressly incorporated by reference herein.

What is claimed is:

1. A method for manufacturing a physical quantity sensor, the method comprising:
preparing a supportive substrate and a seal substrate, the supportive substrate including a first sensor element and a second sensor element disposed therein and the seal substrate including a first accommodation portion and a second accommodation portion disposed on the supportive substrate side thereof and including a through hole that communicates with the first accommodation portion;
bonding the seal substrate to the supportive substrate such that the first sensor element is accommodated on the first accommodation portion side and such that the second sensor element is accommodated on the second accommodation portion side; and
sealing the first accommodation portion by filling the through hole with a seal material that has a lower melting point than the melting points or the softening points of the supportive substrate and the seal substrate.

2. The method for manufacturing a physical quantity sensor according to claim 1,
wherein in the bonding, the second accommodation portion is sealed by bonding the supportive substrate and the seal substrate together.

3. The method for manufacturing a physical quantity sensor according to claim 1,
wherein given that the through hole is a first through hole, the seal material is a first seal material, and the sealing is first sealing,
the seal substrate includes a second through hole that communicates with the second accommodation portion, and
second sealing is further included in which the second accommodation portion is sealed by a second seal material with which the second through hole is filled.

4. The method for manufacturing a physical quantity sensor according to claim 3,
wherein the seal material includes a metal material, and
in the sealing, the first accommodation portion is sealed by melting the seal material.

5. The method for manufacturing a physical quantity sensor according to claim 2,
wherein sealing of the first accommodation portion and sealing of the second accommodation portion are performed in atmospheres that have different pressure.

6. The method for manufacturing a physical quantity sensor according to claim 2,
wherein the first sensor element is a gyrosensor element, and the second sensor element is an acceleration sensor element, and
sealing of the first accommodation portion is performed in a first atmosphere where pressure is lower than atmospheric pressure, and sealing of the second accommodation portion is performed in a second atmosphere where pressure is higher than the pressure in the first atmosphere.

7. The method for manufacturing a physical quantity sensor according to claim 3, further comprising:
first sealing the first accommodation portion by filling the first through hole with the first seal material; and
second sealing the second accommodation portion by filling the second through hole with the second seal material that has a higher melting point than the first seal material.

8. The method for manufacturing a physical quantity sensor according to claim 7,
wherein the first sealing and the second sealing are performed in a same chamber,
in the first sealing, the first seal material is melted by setting the temperature inside the chamber to a first temperature that is higher than at least the melting point of the first seal material, and
in the second sealing, the second seal material is melted by setting the temperature inside the chamber from the first temperature to a second temperature that is higher than at least the melting point of the second seal material.

9. The method for manufacturing a physical quantity sensor according to claim 8, further comprising:
arranging the first seal material in the first through hole and arranging the second seal material in the second through hole before performing the first sealing.

10. A method for manufacturing a physical quantity sensor, the method comprising:
preparing a supportive substrate and a seal substrate, the supportive substrate including a sensor element arranged therein and the seal substrate including a through hole;
bonding the supportive substrate and the seal substrate together such that the sensor element is accommodated in at least an accommodation space that is formed by the supportive substrate and the seal substrate; and
sealing the accommodation space by arranging a seal material in the through hole,
wherein a temperature Ta of the supportive substrate and the seal substrate in the bonding is lower than a melting point Tb of the seal material, and
in the sealing, the through hole is sealed by melting the seal material at a temperature Tc that is higher than or equal to the melting point Tb.

11. The method for manufacturing a physical quantity sensor according to claim 10,
wherein the bonding and the sealing are performed in a same chamber.

12. The method for manufacturing a physical quantity sensor according to claim 11,
wherein after the bonding, the temperature inside the chamber is maintained higher than or equal to the temperature Ta until the through hole is filled with the seal material.

13. The method for manufacturing a physical quantity sensor according to claim 10, further comprising:
arranging the seal material in the through hole before the bonding.

14. A physical quantity sensor comprising:
a supportive substrate;
a first sensor element that is disposed on one face of the supportive substrate;
a second sensor element that is disposed on the one face of the supportive substrate at a position different from the first sensor element;
a seal substrate that includes a first accommodation portion which accommodates the first sensor element, a second accommodation portion which accommodates the second sensor element, a first through hole which communicates with the first accommodation portion, and a second through hole which accommodates with the second accommodation portion and that is bonded to the one face of the supportive substrate;
a first seal material that fills the first through hole and seals the first accommodation portion; and
a second seal material that fills the second through hole and seals the second accommodation portion,
wherein the melting point of the first seal material and the melting point of the second seal material are different from each other.

15. The physical quantity sensor according to claim 14,
wherein each of the melting point of the first seal material and the melting point of the second seal material is lower than the melting points or the softening points of the supportive substrate and the seal substrate.

16. The physical quantity sensor according to claim 14,
wherein the difference between the melting point of the first seal material and the melting point of the second seal material is greater than or equal to 30° C. and less than or equal to 150° C.

17. The physical quantity sensor according to claim 14,
wherein the first sensor element is a gyrosensor element,
the second sensor element is an acceleration sensor element, and
the melting point of the first seal material is lower than the melting point of the second seal material.

18. The physical quantity sensor according to claim 14,
wherein each of the first seal material and the second seal material includes a metal material or a glass material having a low melting point.

19. The physical quantity sensor according to claim 14,
wherein the first through hole includes a part of which the area of the transverse section decreases toward the first accommodation portion.

20. A physical quantity sensor comprising:
a first sensor element;
a supportive substrate in which the first sensor element is arranged;
a seal substrate that is bonded to the supportive substrate, forms a first accommodation space with the supportive substrate, and includes a through hole which reaches the first accommodation space; and
a seal material that seals the through hole,
wherein the first sensor element is accommodated in the first accommodation space, and
the melting point of the seal material is higher than a temperature that is required to bond the supportive substrate and the seal substrate together.

21. The physical quantity sensor according to claim 20,
wherein the through hole includes a part of which the area of the transverse section decreases toward the first accommodation space from the opposite side of the seal substrate from the first accommodation space.

22. The physical quantity sensor according to claim 20, further comprising:
a second accommodation space and a second sensor element, the second accommodation space being formed by bonding the supportive substrate and the seal substrate together and the second sensor element being accommodated in the second accommodation space,
wherein a through hole that reaches the second accommodation space is not formed in the second accommodation space.

23. An electronic device comprising the physical quantity sensor according to claim 14.

24. A moving body comprising the physical quantity sensor according to claim 14.
